(19) United States
(12) Patent Application Publication
(10) Pub. No.: US 2023/0269858 A1
(43) Pub. Date: Aug. 24, 2023

(54) SYSTEMS AND METHODS FOR LASER-TO-DROPLET ALIGNMENT

(71) Applicant: ASML Netherlands B.V., Veldhoven (NL)

(72) Inventors: Poorya Haghi, San Diego, CA (US); Sean W. McGrogan, San Diego, CA (US); Robert N. Jacques, San Diego, CA (US); Daniel Jason Riggs, San Diego, CA (US); Liane Manuela Matthes, San Diego, CA (US)

(21) Appl. No.: 18/010,251

(22) PCT Filed: Jun. 8, 2021
(86) PCT No.: PCT/EP2021/065212

§ 371 Date: Dec. 14, 2022

Related U.S. Application Data
(60) Provisional application No. 63/048,544, filed on Jul. 6, 2020.

(51) Int. Cl. H05G 2/00; G03F 7/20

(52) U.S. Cl. CPC H05G 2/008; G03F 7/70033; H05G 2/005

(57) ABSTRACT

Systems, apparatuses, and methods are provided for steering aligning a laser beam and a fuel target. An example method can include generating, at a first rate, first sensing data indicative of a first overlap between a fuel target and a laser beam. The example method can further include generating, at a second rate, second sensing data indicative of a second overlap between the fuel target and the laser beam. The method can further include generating, at a third rate, and based on the first sensing data and the second sensing data, a steering control signal configured to steer the laser beam or the fuel target. In some aspects, the second rate can be different from the first rate, and the third rate can be about equal to the first rate. In other aspects, the first rate and the second rate can be about equal to the third rate.

### CROSS REFERENCE TO RELATED APPLICATIONS

This application claims priority to U.S. Application No. 63/048,544 filed Jul. 6, 2020 and titled SYSTEMS AND METHODS FOR LASER-TO-DROPLET ALIGNMENT, which is incorporated herein in its entirety by reference.

### TECHNICAL FIELD

The present disclosure relates to systems and methods for using a plurality of control or metrology devices at a radiation source.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is interchangeably referred to as a mask or a reticle, can be used to generate a circuit pattern to be formed on an individual layer of the IC being formed. This pattern can be transferred onto a target portion (e.g., including part of, one, or several dies) on a substrate (e.g., a silicon wafer). Transfer of the pattern is typically via imaging onto a layer of radiation-sensitive material (e.g., resist) provided on the substrate. In general, a single substrate will contain a network of adjacent target portions that are successively patterned. Traditional lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning″-direction) while synchronously scanning the target portions parallel or anti-parallel (e.g., opposite) to this scanning direction. It is also possible to transfer the pattern from the patterning device to the substrate by imprinting the pattern onto the substrate.

As semiconductor manufacturing processes continue to advance, the dimensions of circuit elements have continually been reduced while the amount of functional elements, such as transistors, per device has been steadily increasing over decades, following a trend commonly referred to as Moore’s law. To keep up with Moore’s law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Extreme ultraviolet (EUV) radiation, for example, electromagnetic radiation having wavelengths of around 50 nanometers (nm) or less (also sometimes referred to as soft x-rays), and including light at a wavelength of about 13 nm, can be used in or with a lithographic apparatus to produce extremely small features in or on substrates, for example, silicon wafers. A lithographic apparatus which uses EUV radiation having a wavelength within a range of 4 nm to 20 nm, for example 6.7 nm or 13.5 nm, can be used to form smaller features on a substrate than a lithographic apparatus which uses, for example, radiation with a wavelength of 193 nm.

Methods to produce EUV light include, but are not necessarily limited to, converting a material that has an element, for example, xenon (Xe), lithium (Li), or tin (Sn), with an emission line in the EUV range to a plasma state. For example, in one such method called laser produced plasma (LPP), the plasma can be produced by irradiating a target material, which is interchangeably referred to as fuel in the context of LPP sources, for example, in the form of a droplet, plate, tape, stream, or cluster of material, with an amplified light beam that can be referred to as a drive laser. For this process, the plasma is typically produced in a sealed vessel, for example, a vacuum chamber, and monitored using various types of metrology equipment.

### SUMMARY

The present disclosure describes various aspects of systems, apparatuses, and methods for providing model-based estimation of laser-to-droplet (L2D) alignment using, in some aspects, two optical sensing devices. In some aspects, the two optical sensing devices can include a photoreceiver (e.g., a quadrant-cell photoreceiver (quad-cell)) configured to generate first sensing data at a first rate (e.g., 50 kHz) and an imaging device (e.g., a photodetector, photodiode, camera, or other suitable device) configured to generate second sensing data at a second rate (e.g., 5 Hz) that, in some aspects, can be less than the first rate. In other aspects, the two optical sensing devices can include two synchronized imaging devices, such as two droplet formation cameras (DFCs), configured to provide stereoscopic vision.

In some aspects, the present disclosure describes a radiation source. The radiation source can include a first optical sensing device configured to generate, at a first rate, first sensing data indicative of a first overlap between a fuel target and a laser beam. In some aspects, the first optical sensing device can be configured to obtain the first sensing data from a first angle. The radiation source can further include a second imaging device configured to generate, at a second rate, second sensing data indicative of a second overlap between the fuel target and the laser beam. In some aspects, the second optical sensing device can be configured to obtain the second sensing data from a second angle different from the first angle. The radiation source can further include a controller configured to: receive the first sensing data and the second sensing data. The controller can be further configured to generate fuel target data based on the first sensing data and the second sensing data. The fuel target data can be indicative of a set of properties of the fuel target (e.g., detected, measured, captured, obtained, or actual properties associated with the fuel target or modified fuel target). In some aspects, the fuel target data can include laser-to-droplet (L2D) data. In some aspects, the controller can be further configured to: generate stereoscopic sensing data based on the first sensing data and the second sensing data; and generate the fuel target data based on the stereoscopic sensing data. The controller can be further configured to generate, at a third rate and based on the fuel target data, a steering control signal configured to steer the laser beam or the fuel target.

In some aspects, the first optical sensing device can include a photoreceiver (e.g., a quad-cell), and the second optical sensing device can include an imaging device (e.g., a camera). In some aspects, the second rate can be different from the first rate. For example, the first rate can be about 50 kHz and the second rate can be about 5 Hz. In some aspects, the third rate can be about equal to the first rate. For example, the third rate can be about 50 kHz.

In some aspects, the first optical sensing device can include a first droplet formation camera (DFC). In some aspects, the second optical sensing device can include a second DFC configured to be synchronized to the first DFC. In some aspects, the second rate can be about equal to the first rate. In some aspects, the third rate can be about equal to the first rate. For example, each of the first rate, the second rate, and the third rate can be about equal to 5 Hz. In some aspects, the radiation source can further include a dual DFC system including the first DFC, the second DFC, a first illumination device, and a second illumination device. In some aspects, the first sensing data can be indicative of the first overlap between the fuel target and the laser beam obtained from a first angle at about a time that the laser beam is generated. In some aspects, the second sensing data can be indicative of the second overlap between the fuel target and the laser beam obtained from a second angle different from first angle at about the time that the laser beam is generated. In some aspects, the first illumination device can be configured to illuminate the fuel target from a first illumination angle at about the time that the laser beam is generated. In some aspects, the second illumination device can be configured to illuminate the fuel target from a second illumination angle different from the first illumination angle at about the time that the laser beam is generated. In some aspects, the laser beam can include a pre-pulse laser beam.

In some aspects, the controller can be further configured to generate first estimated fuel target data. The first estimated fuel target data can be indicative of a first set of estimated properties of the fuel target. In some aspects, the controller can be further configured to generate a comparison of the fuel target data and the first estimated fuel target data. In some aspects, the controller can be further configured to generate fuel target estimation error data based on the comparison. In some aspects, the controller can be further configured to generate second estimated fuel target data based on the fuel target data, the first estimated fuel target data, and the fuel target estimation error data. The second estimated fuel target data can be indicative of a second set of estimated properties of the fuel target.

In some aspects, where the steering control signal is a first steering control signal, the controller can be further configured to: generate, at a first time, the first steering control signal based on the fuel target data; and generate, at a second time different from the first time, a second steering control signal based on the second estimated fuel target data.

In some aspects, where the comparison is a first comparison and the fuel target estimation error data is first fuel target estimation error data, the controller can be further configured to: generate a second comparison of the fuel target data and the second estimated fuel target data; and generate second fuel target estimation error data based on the second comparison. The second fuel target estimation error data can indicate an absence of an error between the fuel target data and the second estimated fuel target data. For example, the controller can be configured to determine that the error between the fuel target data and the second estimated fuel target data is below an error tolerance value (e.g., +/- 2 percent, +/- 5 percent, or any other suitable value or range), and in response to the determination, determine that the second fuel target estimation error data indicates an absence of an error between the fuel target data and the second estimated fuel target data.

In some aspects, the radiation source can further include a laser steering system. In some aspects, the steering control signal can include a laser steering control signal indicative of an electronic instruction to steer the laser beam towards a plasma generation region. In some aspects, the controller can be further configured to transmit the laser steering control signal to the laser steering system. In some aspects, the laser steering system can include a laser steering actuator configured to: receive the laser steering control signal; and steer the laser beam towards the plasma generation region based on the laser steering control signal.

In some aspects, the radiation source can further include a fuel target steering system. In some aspects, the steering control signal can include a fuel target steering control signal indicative of an electronic instruction to steer the fuel target towards a plasma generation region. In some aspects, the controller can be configured to transmit the fuel target steering control signal to the fuel target steering system. In some aspects, the fuel target steering system can include a fuel target steering actuator configured to: receive the fuel target steering control signal; and steer the fuel target towards the plasma generation region based on the fuel target steering control signal.

In some aspects, the steering control signal can include a laser steering control signal indicative of a first electronic instruction to steer the laser beam. In some aspects, the controller can be further configured to transmit the laser steering control signal to a laser steering system. In some aspects, the steering control signal can further include a fuel target steering control signal indicative of a second electronic instruction to steer the fuel target. In some aspects, the controller can be further configured to transmit the fuel target steering control signal to a fuel target steering system.

In some aspects, the present disclosure describes an apparatus. The apparatus can include a controller. The controller can be configured to receive first sensing data captured at a first rate and indicative of a first overlap between a fuel target and a laser beam obtained from a first angle. The controller can be further configured to receive second sensing data captured at a second rate and indicative of a second overlap between the fuel target and the laser beam obtained from a second angle different from the first angle. The controller can be further configured to generate fuel target data based on the first sensing data and the second sensing data. The controller can be further configured to generate estimated fuel target data. The controller can be further configured to generate a comparison of the fuel target data and the estimated fuel target data. The controller can be further configured to generate fuel target estimation error data based on the comparison. The controller can be further configured to generate modified estimated fuel target data based on the fuel target data, the estimated fuel target data, and the fuel target estimation error data. The controller can be further configured to generate, at a third rate and based on the modified estimated target data, a steering control signal configured to steer the laser beam or the fuel target.

In some aspects, the controller can be further configured to receive the first sensing data from a first optical sensing device that includes a photoreceiver (e.g., a quad-cell). In some aspects, the controller can be further configured to receive the second sensing data from a second optical sensing device that includes an imaging device (e.g., a camera). In some aspects, the second rate can be different from the first rate. For example, the first rate can be about 50 kHz and the second rate can be about 5 Hz. In some aspects, the third rate can be about equal to the first rate. For example, the third rate can be about 50 kHz.

In some aspects, the controller can be further configured to receive the first sensing data from a first optical sensing device that includes a first droplet formation camera. In some aspects, the controller can be further configured to receive the second sensing data from a second optical sensing device that includes a second droplet formation camera configured to be synchronized to the first droplet formation camera. In some aspects, the second rate can be about equal to the first rate. In some aspects, the third rate can be about equal to the first rate. For example, each of the first rate, the second rate, and the third rate can be about equal to 5 Hz.

In some aspects, the steering control signal can include a laser steering control signal indicative of an electronic instruction to steer the laser beam towards a plasma generation region. In some aspects, the controller can be further configured to transmit the laser steering control signal to a laser steering system.

In some aspects, the steering control signal can include a fuel target steering control signal indicative of an electronic instruction to steer the fuel target towards a plasma generation region. In some aspects, the controller can be further configured to transmit the fuel target steering control signal to a fuel target steering system.

In some aspects, the present disclosure describes a method for aligning a laser beam and a fuel target and, in some instances, steering the laser beam, the fuel target, or both. The method can include generating, by a first optical sensing device, first sensing data indicative of a first overlap between a fuel target and a laser beam obtained from a first angle. The method can further include generating, by a second optical sensing device, second sensing data indicative of a second overlap between the fuel target and the laser beam obtained from a second angle different from the first angle. The method can further include generating, by a controller, fuel target data based on the first sensing data and the second sensing data. The fuel target data can be indicative of a set of properties of the fuel target.

The method can further include generating, by the controller, first estimated fuel target data. The first estimated fuel target data can be indicative of a first set of estimated properties of the fuel target. The method can further include generating, by the controller, a comparison of the fuel target data and the first estimated fuel target data. The method can further include generating, by the controller, fuel target estimation error data based on the comparison. The method can further include generating, by the controller, second estimated fuel target data based on the fuel target data, the first estimated fuel target data, and the fuel target estimation error data. The second estimated fuel target data can be indicative of a second set of estimated properties of the fuel target. The method can further include generating, by the controller and based on the second estimated target data, a steering control signal configured to steer the laser beam or the fuel target.

In some aspects, the method can include generating, by the first optical sensing device, the first sensing data at a first rate; generating, by the second optical sensing device, the second sensing data at a second rate; and generating, by the controller, the steering control signal at a third rate.

In some aspects, the first optical sensing device can include a photoreceiver (e.g., a quad-cell), and the second optical sensing device can include an imaging device (e.g., a camera). In some aspects, the second rate can be different from the first rate. For example, the first rate can be about 50 kHz and the second rate can be about 5 Hz. In some aspects, the third rate can be about equal to the first rate. For example, the third rate can be about 50 kHz.

In some aspects, the first optical sensing device can include a first DFC. In some aspects, the second optical sensing device can include a second DFC configured to be synchronized to the first DFC. In some aspects, the second rate can be about equal to the first rate. In some aspects, the third rate can be about equal to the first rate. For example, each of the first rate, the second rate, and the third rate can be about equal to 5 Hz.

In some aspects, the steering control signal can include a laser steering control signal indicative of an electronic instruction to steer the laser beam towards a plasma generation region. In some aspects, the method can further include steering, by a laser steering actuator of a laser steering system, the laser beam towards the plasma generation region based on the laser steering control signal.

In some aspects, the steering control signal can include a fuel target steering control signal indicative of an electronic instruction to steer the fuel target towards a plasma generation region. In some aspects, the method can further include steering, by a fuel target steering actuator of a fuel target steering system, the fuel target towards the plasma generation region based on the fuel target steering control signal.

Further features and advantages, as well as the structure and operation of various aspects, are described in detail below with reference to the accompanying drawings. It is noted that the disclosure is not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the aspects of this disclosure and to enable a person skilled in the relevant art(s) to make and use the aspects of this disclosure.

FIG. 1A is a schematic illustration of an example reflective lithographic apparatus according to some aspects of the present disclosure.

FIG. 1B is a schematic illustration of an example transmissive lithographic apparatus according to some aspects of the present disclosure.

FIG. 2 is a more detailed schematic illustration of the reflective lithographic apparatus shown in FIG. 1A according to some aspects of the present disclosure.

FIG. 3 is a schematic illustration of an example lithographic cell according to some aspects of the present disclosure.

FIG. 4 is a schematic illustration of an example radiation source for an example reflective lithographic apparatus according to some aspects of the present disclosure.

FIG. 5 is a schematic illustration of an example L2D alignment system according to some aspects of the present disclosure.

FIG. 6 is a schematic illustration of an example fuel target sensing system according to some aspects of the present disclosure.

FIG. 7 is a schematic illustration of an example L2D alignment process according to some aspects of the present disclosure.

FIG. 8 shows a set of example graphs associated with an example L2D alignment process according to some aspects of the present disclosure.

FIG. 9 is an example method for aligning a laser beam and a fuel target according to some aspects of the present disclosure or portion(s) thereof.

FIG. 10 is an example computer system for implementing some aspects of the present disclosure or portion(s) thereof.

The features and advantages of the present disclosure will become more apparent from the detailed description set forth below when taken in conjunction with the drawings, in which like reference characters identify corresponding elements throughout. In the drawings, unless otherwise indicated, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) merely describe the present disclosure. The scope of the disclosure is not limited to the disclosed embodiment(s). The breadth and scope of the disclosure are defined by the claims appended hereto and their equivalents.

The embodiment(s) described, and references in the specification to “one embodiment,” “an embodiment,” “an exemplary embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

### Overview

In one example, an EUV source can measure the accuracy with which the laser beams hit droplets via a characteristic called laser-to-droplet (L2D). L2D can be a relative indicator of position of center of mass of the droplet in the center of mass of the pre-pulse laser beam. The accuracy of the L2D measurements can be paramount in the performance of the EUV light source and thus any improvements in L2D metrology can improve the efficiency of the EUV light source.

In one example, two different approaches can be used for L2D metrology: (i) final focus metrology (FFM) cameras; and (ii) FFM quad-cells. Both of these methods are based on the same principle. As the pre-pulse laser beam is traveling in its forward path (e.g., forward beam), the pre-pulse laser beam passes through a region referred to as a “diamond window” where part of the laser is directed towards a forward beam diagnostics (FBD) imaging sensor that includes either FFM cameras or FFM quad-cells. Subsequently, the location of the center of the laser is calculated.

Once the laser hits the droplet, light reflects back from the droplet and traverses through the same path it came from, hitting the diamond window on its way back, where part of the reflected laser is directed towards a reverse beam diagnostics (RBD) imaging sensor that includes either FFM cameras or FFM quad-cells. Subsequently, the location of the center of this reflected laser is calculated, representing the location of the droplet. The difference between the measurements of FBD imaging sensor and the RBD imaging sensor provides a relative measure of where the droplet is located in the laser, also referred to as L2D. The FFM quad-cell measurements are provided at 50 kHz (e.g., “shot-to-shot” for every instance of laser hitting the droplet), while the FFM cameras measurements are provided at much lower frequencies.

However, the direct interaction of the FFM metrology (e.g., FFM cameras, FFM quad-cells) with the high power laser beam can have several major downsides. Depending on the laser power, or duty cycle, the intensity of light on the image sensor changes. This requires the use of several filters from light to dark to account for variations in light intensity. Misuse of the filters can lead to sensor damage when there is too much intensity (e.g., which translates to loss time to service the machine) or no sensor data when the filters are too dark (e.g., which leads to bad dose performance and lot aborts). In addition, the direct contact with the high power laser can create a significant thermal transient which can misalign the optics over time and create a drift in the measurements. As a result of this drift, production must be stopped periodically to calibrate the EUV source. For example, a gradual drift in the L2D measurement can eventually lead to inadequate EUV source performance and require costly and time-consuming service actions to remedy that performance. In another example, the impact of the L2D drift on EUV source that EUV radiation measurements drop between 0.2 to 0.5 millijoules (mJ) on all EUV side sensors.

In addition, FBD or RBD imaging sensors having FFM cameras produce results that are different from FBD or RBD imaging sensors having FFM quad-cells, even though the actual position of the laser is the same. In other words, FFM-cameras-based L2D measurements are different from FFM-quad-cells-based L2D measurements when they should be equal. For example, in the same time period that FFM Cameras L2D measurements are observed to be drifting, FFM quad-cells show a constant value for L2D. Further, the absolute values of these measurements do not match. Both FFM cameras and FFM quad-cells measure L2D by the same technique and should be consistent yet they are not.

Further still, it might not be possible to know where the beam waist is located based on the FFM sensor data without performing a scan, which requires stopping lot production. Additionally, due to its complicated design, service actions on FFM sensors are expensive and time consuming.

In contrast, some aspects of the present disclosure can provide systems, apparatuses, methods, and computer program products for estimating L2D that is inexpensive (e.g., low cost of hardware and repair) and not prone to the aforementioned thermal drifts. For example, the L2D measurement hardware is mounted outside the vessel and thus the metrology does not suffer from laser-induced thermal transients (e.g., meaning no drifts). Moreover, repair actions are simplified due to the outside mount, In some aspects, the present disclosure provides for a model-based estimation of L2D alignment using two cameras for stereoscopic vision.

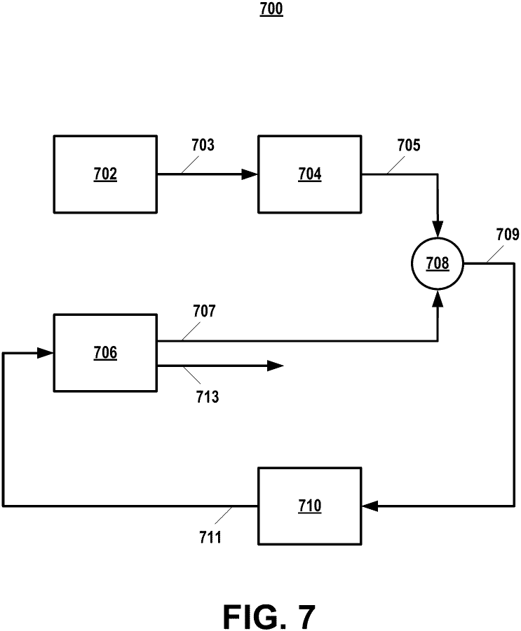

In some aspects, the present disclosure provides for the use of first sensing data (e.g., quad-cell data) acquired by a photoreceiver (e.g., a quad-cell) in conjunction with second sensing data (e.g., image data) acquired by an imaging device (e.g., a camera). In some aspects, the present disclosure provides for various types of inputs and outputs that can be used in the feedback control process for the L2D alignment. The inputs can include, for example, (a) quad-cell data (e.g., updated at a faster rate such as 50 kHz), (b) image data (e.g., updated at a lower rate such as 5 Hz), and (c) steering data (e.g., updated a faster rate such as at 50 kHz). The outputs can include, for example, (d) a control signal that steers the laser beam, a control signal that steers the fuel targets, or one or more control signals that steer both the laser beam and the fuel targets. In some aspects, the present disclosure provides for feedback loops configured to drive the target angle measurements (e.g., angles Rx and Ry) to target angle setpoints. In some aspects, the present disclosure provides for feedback loops configured to drive estimated L2D values to the L2D setpoints (e.g., using a Kalman filter at block 710 as described with reference to FIG. 7).

In some aspects, the present disclosure provides for using two backlight laser modules (BLMs) that shine on the fuel target at two different angles as the fuel target travels from the fuel target generator (e.g., droplet generator DG) to the fuel target catch (e.g., tin catch TC). Next, two synchronized DFCs simultaneously take the picture of the fuel target. The use of two DFCs instead of one provides for the generation of a three-dimensional perception of the target, also referred to as stereoscopic imaging. This hardware (e.g., the two BLMs and the two DFCs) is installed outside of the pressurized vessel and thus is easily replaceable for repairs. Moreover, unlike the FFM-based hardware, this hardware does not directly contact the high power laser and thus does not suffer from thermal transients and drifts.

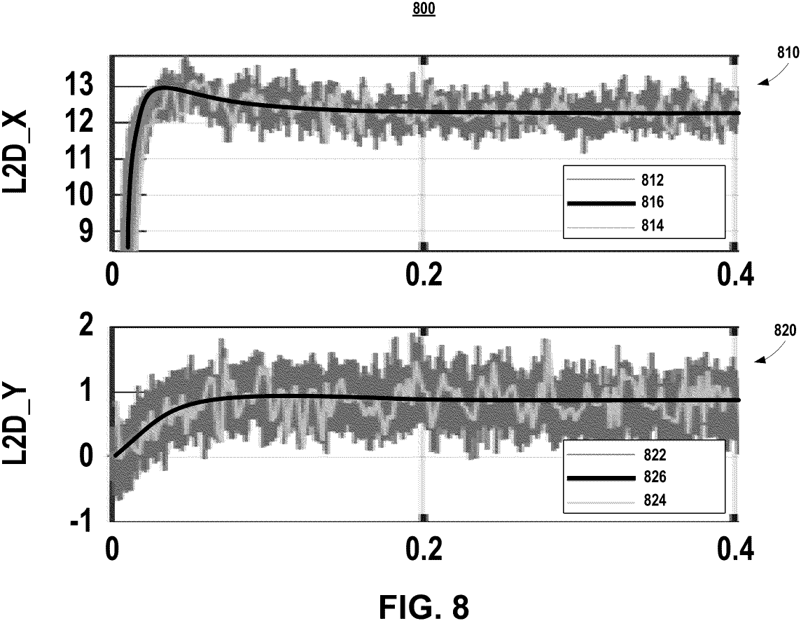

In some aspects, the sensing data (e.g., including, but not limited to, captured images) from the two DFCs is transferred to a local controller for further processing as described herein. Once the sensing data is transferred to the local controller, the local controller processes the sensing data to extract the L2D from the captured sensing data. For example, the local controller can include an L2D estimator that uses a mathematical model of the EUV source to map L2D values into geometrical target properties such as target shape, size, and orientation. In some aspects, the L2D estimator starts by determining an initial L2D value and calculating estimated target properties using mathematical equations. The L2D estimator then compares the estimated target properties to actual measurements of target properties obtained by the two DFCs as described above. This comparison provides a measure for error in the L2D estimation. The error is then recursively fed back to the L2D estimator until the L2D estimator determines values for the estimated target properties that make the estimation error zero. In one illustrative example, this can be done via updating the Kalman gain at each step, which ensures fast convergence of the L2D estimator and has the additional advantage of compensating for noisy measurements coming from the hardware. FIG. 8 shows how the estimated L2D value is converging to the real L2D value compared to the noisier L2D measurements.

In some aspects, the present disclosure provides a method for estimating L2D that includes: using two BLMs to illuminate a fuel target at two different angles; using two DFCs to capture a fuel target image at two different angles; reconstructing a three-dimensional stereoscopic image of the fuel target from the two two-dimensional images captured by the two DFCs; using a mathematical model that correlates L2D to the geometrical properties of the fuel target; and using a Kalman filter estimator that back calculates L2D from the measurements obtained from the stereoscopic image of the fuel target.

In some aspects, the present disclosure describes a method for steering a laser beam, a fuel target, or both. The method can include generating first sensing data indicative of a first overlap between a fuel target and a laser beam obtained from a first angle. The method can further include generating second sensing data indicative of a second overlap between the fuel target and the laser beam obtained from a second angle different from the first angle. The method can further include generating fuel target data based on the first sensing data and the second sensing data. The fuel target data can be indicative of a set of properties of the fuel target. In some aspects, method can further include generating first estimated fuel target data. The first estimated fuel target data can be indicative of a first set of estimated properties of the fuel target. The method can further include generating a comparison of the fuel target data and the first estimated fuel target data. The method can further include generating fuel target estimation error data based on the comparison. The method can further include generating second estimated fuel target data based on the fuel target data, the first estimated fuel target data, and the fuel target estimation error data. The second estimated fuel target data can be indicative of a second set of estimated properties of the fuel target. The method can further include generating, based on the second estimated target data, a steering control signal configured to steer the laser beam or the fuel target.

There are many benefits to the systems, apparatuses, methods, and computer program products disclosed herein. For example, the present disclosure provides for an absolute L2D measurement where the L2D alignment of zero in the X and Y directions corresponds to target angle of zero on all structures, and the L2D alignment of zero in the Z direction defines the beam waist (e.g., structure-to-structure matching). In another example, the present disclosure provides for an L2D measurement that is not prone to thermal drifts and thus can be used to correct the bias and error in the FFM metrology techniques described above, which can lead to higher EUV source productivity. In yet another example, the present disclosure provides for cost reduction in the FFM system by relaxing the requirements on the FFM control loops. In yet another example, the present disclosure provides for reductions in mean time to repair (MTTR) and mean time between intervals (MTBI).

Before describing such aspects in more detail, however, it is instructive to present an example environment in which aspects of the present disclosure can be implemented.

### Example Lithographic Systems

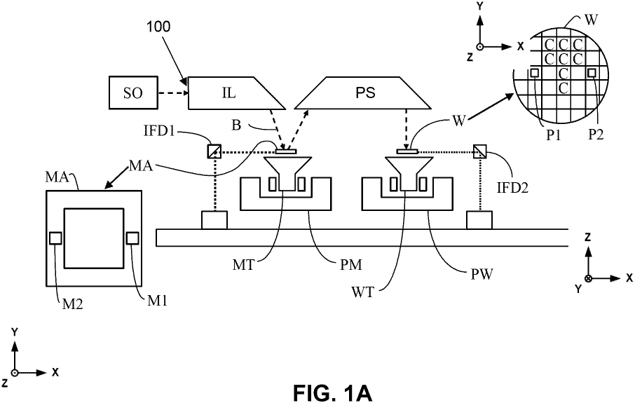

FIGS. 1A and 1B are schematic illustrations of a lithographic apparatus 100 and lithographic apparatus 100′, respectively, in which aspects of the present disclosure can be implemented. As shown in FIGS. 1A and 1B, the lithographic apparatuses 100 and 100′ are illustrated from a point of view (e.g., a side view) that is normal to the XZ plane (e.g., the X-axis points to the right, the Z-axis points upward, and the Y-axis points into the page away from the viewer), while the patterning device MA and the substrate W are presented from additional points of view (e.g., a top view) that are normal to the XY plane (e.g., the X-axis points to the right, the Y-axis points upward, and the Z-axis points out of the page toward the viewer).

In some aspects, the lithographic apparatus 100 and/or the lithographic apparatus 100′ can include one or more of the following structures: an illumination system IL (e.g., an illuminator) configured to condition a radiation beam B (e.g., a deep ultra violet (DUV) radiation beam or an extreme ultra violet (EUV) radiation beam); a support structure MT (e.g., a mask table) configured to support a patterning device MA (e.g., a mask, a reticle, or a dynamic patterning device) and connected to a first positioner PM configured to accurately position the patterning device MA; and, a substrate holder such as a substrate table WT (e.g., a wafer table) configured to hold a substrate W (e.g., a resist-coated wafer) and connected to a second positioner PW configured to accurately position the substrate W. Lithographic apparatuses 100 and 100′ also have a projection system PS (e.g., a refractive projection lens system) configured to project a pattern imparted to the radiation beam B by patterning device MA onto a target portion C (e.g., a portion including one or more dies) of the substrate W. In lithographic apparatus 100, the patterning device MA and the projection system PS are reflective. In lithographic apparatus 100′, the patterning device MA and the projection system PS are transmissive.

In some aspects, in operation, the illumination system IL can receive a radiation beam from a radiation source SO (e.g., via a beam delivery system BD shown in FIG. 1B). The illumination system IL can include various types of optical structures, such as refractive, reflective, catadioptric, magnetic, electromagnetic, electrostatic, and other types of optical components, or any combination thereof, for directing, shaping, or controlling radiation. In some aspects, the illumination system IL can be configured to condition the radiation beam B to have a desired spatial and angular intensity distribution in its cross-section at a plane of the patterning device MA.

In some aspects, the support structure MT can hold the patterning device MA in a manner that depends on the orientation of the patterning device MA with respect to a reference frame, the design of at least one of the lithographic apparatuses 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

In some aspects, the patterning device MA can be transmissive (as in lithographic apparatus 100′ of FIG. 1B) or reflective (as in lithographic apparatus 100 of FIG. 1A). The patterning device MA can include various structures such as reticles, masks, programmable mirror arrays, programmable LCD panels, other suitable structures, or combinations thereof. Masks can include mask types such as binary, alternating phase shift, or attenuated phase shift, as well as various hybrid mask types. In one example, a programmable mirror array can include a matrix arrangement of small mirrors, each of which can be individually tilted so as to reflect an incoming radiation beam in different directions. The tilted mirrors can impart a pattern in the radiation beam B, which is reflected by a matrix of small mirrors.

The term “projection system” PS should be interpreted broadly and can encompass any type of projection system, including refractive, reflective, catadioptric, magnetic, anamorphic, electromagnetic, and electrostatic optical systems, or any combination thereof, as appropriate for the exposure radiation being used, and/or for other factors such as the use of an immersion liquid (e.g., on the substrate W) or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps. In addition, any use herein of the term “projection lens” can be interpreted, in some aspects, as synonymous with the more general term “projection system” PS.

In some aspects, the lithographic apparatus 100 and/or the lithographic apparatus 100′ can be of a type having two (e.g., “dual stage”) or more substrate tables WT and/or two or more mask tables). In such “multiple stage” machines, the additional substrate tables WT can be used in parallel, or preparatory steps can be carried out on one or more tables while one or more other substrate tables WT are being used for exposure. In one example, steps in preparation of a subsequent exposure of the substrate W can be carried out on the substrate W located on one of the substrate tables WT while another substrate W located on another of the substrate tables WT is being used for exposing a pattern on another substrate W. In some aspects, the additional table may not be a substrate table WT.

In some aspects, in addition to the substrate table WT, the lithographic apparatus 100 and/or the lithographic apparatus 100′ can include a measurement stage. The measurement stage can be arranged to hold a sensor. The sensor can be arranged to measure a property of the projection system PS, a property of the radiation beam B, or both. In some aspects, the measurement stage can hold multiple sensors. In some aspects, the measurement stage can move beneath the projection system PS when the substrate table WT is away from the projection system PS.

In some aspects, the lithographic apparatus 100 and/or the lithographic apparatus 100′ can also be of a type wherein at least a portion of the substrate can be covered by a liquid having a relatively high refractive index, e.g., water, so as to fill a space between the projection system PS and the substrate W. An immersion liquid can also be applied to other spaces in the lithographic apparatus, for example, between the patterning device MA and the projection system PS. Immersion techniques provide for increasing the numerical aperture of projection systems. The term “immersion” as used herein does not mean that a structure, such as a substrate, must be submerged in liquid, but rather only means that liquid is located between the projection system and the substrate during exposure. Various immersion techniques are described in U.S. Pat. No. 6,952,253, issued Oct. 4, 2005, and titled “LITHOGRAPHIC APPARATUS AND DEVICE MANUFACTURING METHOD,” which is incorporated by reference herein in its entirety.

Referring to FIGS. 1A and 1B, the illumination system IL receives a radiation beam B from a radiation source SO. The radiation source SO and the lithographic apparatus 100 or 100′ can be separate physical entities, for example, when the radiation source SO is an excimer laser. In such cases, the radiation source SO is not considered to form part of the lithographic apparatus 100 or 100′, and the radiation beam B passes from the radiation source SO to the illumination system IL with the aid of a beam delivery system BD (e.g., shown in FIG. 1B) including, for example, suitable directing mirrors and/or a beam expander. In other cases, the radiation source SO can be an integral part of the lithographic apparatus 100 or 100′, for example, when the radiation source SO is a mercury lamp. The radiation source SO and the illuminator IL, together with the beam delivery system BD, if required, can be referred to as a radiation system.

In some aspects, the illumination system IL can include an adjuster AD for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illumination system IL can include various other components, such as an integrator IN and a radiation collector CO (e.g., a condenser or collector optic). In some aspects, the illumination system IL can be used to condition the radiation beam B to have a desired uniformity and intensity distribution in its cross section.

Referring to FIG. 1A, in operation, the radiation beam B can be incident on the patterning device MA (e.g., a mask, reticle, programmable mirror array, programmable LCD panel, any other suitable structure or combination thereof), which can be held on the support structure MT (e.g., a mask table), and can be patterned by the pattern (e.g., design layout) present on the patterning device MA. In lithographic apparatus 100, the radiation beam B can be reflected from the patterning device MA. Having traversed (e.g., after being reflected from) the patterning device MA, the radiation beam B can pass through the projection system PS, which can focus the radiation beam B onto a target portion C of the substrate W or onto a sensor arranged at a stage.

In some aspects, with the aid of the second positioner PW and position sensor IFD2 (e.g., an interferometric device, linear encoder, or capacitive sensor), the substrate table WT can be moved accurately, e.g., so as to position different target portions C in the path of the radiation beam B. Similarly, the first positioner PM and another position sensor IFD1 (e.g., an interferometric device, linear encoder, or capacitive sensor) can be used to accurately position the patterning device MA with respect to the path of the radiation beam B.

In some aspects, patterning device MA and substrate W can be aligned using mask alignment marks M1 and M2 and substrate alignment marks P1 and P2. Although FIGS. 1A and 1B illustrate the substrate alignment marks P1 and P2 as occupying dedicated target portions, the substrate alignment marks P1 and P2 may be located in spaces between target portions. Substrate alignment marks P1 and P2 are known as scribe-lane alignment marks when they are located between the target portions C. Substrate alignment marks P1 and P2 can also be arranged in the target portion C area as in-die marks. These in-die marks can also be used as metrology marks, for example, for overlay measurements.

In some aspects, for purposes of illustration and not limitation, one or more of the figures herein can utilize a Cartesian coordinate system. The Cartesian coordinate system includes three axes: an X-axis; a Y-axis; and a Z-axis. Each of the three axes is orthogonal to the other two axes (e.g., the X-axis is orthogonal to the Y-axis and the Z-axis, the Y-axis is orthogonal to the X-axis and the Z-axis, the Z-axis is orthogonal to the X-axis and the Y-axis). A rotation around the X-axis is referred to as an Rx-rotation. A rotation around the Y-axis is referred to as an Ry-rotation. A rotation around about the Z-axis is referred to as an Rz-rotation. In some aspects, the X-axis and the Y-axis define a horizontal plane, whereas the Z-axis is in a vertical direction. In some aspects, the orientation of the Cartesian coordinate system may be different, for example, such that the Z-axis has a component along the horizontal plane. In some aspects, another coordinate system, such as a cylindrical coordinate system, can be used.

Referring to FIG. 1B, the radiation beam B is incident on the patterning device MA, which is held on the support structure MT, and is patterned by the patterning device MA. Having traversed the patterning device MA, the radiation beam B passes through the projection system PS, which focuses the beam onto a target portion C of the substrate W. In some aspects, the projection system PS can have a pupil conjugate to an illumination system pupil. In some aspects, portions of radiation can emanate from the intensity distribution at the illumination system pupil and traverse a mask pattern without being affected by diffraction at the mask pattern MP and create an image of the intensity distribution at the illumination system pupil.

The projection system PS projects an image MP′ of the mask pattern MP, where image MP′ is formed by diffracted beams produced from the mask pattern MP by radiation from the intensity distribution, onto a resist layer coated on the substrate W. For example, the mask pattern MP can include an array of lines and spaces. A diffraction of radiation at the array and different from zeroth-order diffraction generates diverted diffracted beams with a change of direction in a direction perpendicular to the lines. Undiffracted beams (e.g., so-called zeroth-order diffracted beams) traverse the pattern without any change in propagation direction. The zeroth-order diffracted beams traverse an upper lens or upper lens group of the projection system PS, upstream of the pupil conjugate of the projection system PS, to reach the pupil conjugate. The portion of the intensity distribution in the plane of the pupil conjugate and associated with the zeroth-order diffracted beams is an image of the intensity distribution in the illumination system pupil of the illumination system IL. In some aspects, an aperture device can be disposed at, or substantially at, a plane that includes the pupil conjugate of the projection system PS.

The projection system PS is arranged to capture, by means of a lens or lens group, not only the zeroth-order diffracted beams, but also first-order or first- and higher-order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the substrate W to create an image of the mask pattern MP at highest possible resolution and process window (e.g., usable depth of focus in combination with tolerable exposure dose deviations). In some aspects, astigmatism aberration can be reduced by providing radiation poles (not shown) in opposite quadrants of an illumination system pupil. Further, in some aspects, astigmatism aberration can be reduced by blocking the zeroth-order beams in the pupil conjugate of the projection system PS associated with radiation poles in opposite quadrants. This is described in more detail in U.S. Pat. No. 7,511,799, issued Mar. 31, 2009, and titled “LITHOGRAPHIC PROJECTION APPARATUS AND A DEVICE MANUFACTURING METHOD,” which is incorporated by reference herein in its entirety.

In some aspects, with the aid of the second positioner PW and a position measurement system PMS (e.g., including a position sensor such as an interferometric device, linear encoder, or capacitive sensor), the substrate table WT can be moved accurately, e.g., so as to position different target portions C in the path of the radiation beam B at a focused and aligned position. Similarly, the first positioner PM and another position sensor (e.g., an interferometric device, linear encoder, or capacitive sensor) (not shown in FIG. 1B) can be used to accurately position the patterning device MA with respect to the path of the radiation beam B (e.g., after mechanical retrieval from a mask library or during a scan). Patterning device MA and substrate W can be aligned using mask alignment marks M1 and M2 and substrate alignment marks P1 and P2.

In general, movement of the support structure MT can be realized with the aid of a long-stroke positioner (coarse positioning) and a short-stroke positioner (fine positioning), which form part of the first positioner PM. Similarly, movement of the substrate table WT can be realized using a long-stroke positioner and a short-stroke positioner, which form part of the second positioner PW. In the case of a stepper (as opposed to a scanner), the support structure MT can be connected to a short-stroke actuator only or can be fixed. Patterning device MA and substrate W can be aligned using mask alignment marks M1 and M2, and substrate alignment marks P1 and P2. Although the substrate alignment marks (as illustrated) occupy dedicated target portions, they can be located in spaces between target portions (e.g., scribe-lane alignment marks). Similarly, in situations in which more than one die is provided on the patterning device MA, the mask alignment marks M1 and M2 can be located between the dies.

Support structure MT and patterning device MA can be in a vacuum chamber V, where an in-vacuum robot can be used to move patterning devices such as a mask in and out of vacuum chamber. Alternatively, when support structure MT and patterning device MA are outside of the vacuum chamber, an out-of-vacuum robot can be used for various transportation operations, similar to the in-vacuum robot. In some instances, both the in-vacuum and out-of-vacuum robots need to be calibrated for a smooth transfer of any payload (e.g., a mask) to a fixed kinematic mount of a transfer station.

In some aspects, the lithographic apparatuses 100 and 100′ can be used in at least one of the following modes:

1. In step mode, the support structure MT and the substrate table WT are kept essentially stationary, while an entire pattern imparted to the radiation beam B is projected onto a target portion C at one time (e.g., a single static exposure). The substrate table WT is then shifted in the X and/or Y direction so that a different target portion C can be exposed.

2. In scan mode, the support structure MT and the substrate table WT are scanned synchronously while a pattern imparted to the radiation beam B is projected onto a target portion C (e.g., a single dynamic exposure). The velocity and direction of the substrate table WT relative to the support structure MT (e.g., mask table) can be determined by the (de-)magnification and image reversal characteristics of the projection system PS.

3. In another mode, the support structure MT is kept substantially stationary holding a programmable patterning device MA, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device MA, such as a programmable mirror array.

In some aspects, the lithographic apparatuses 100 and 100′ can employ combinations and/or variations of the above-described modes of use or entirely different modes of use.

In some aspects, as shown in FIG. 1A, the lithographic apparatus 100 can include an EUV source configured to generate an EUV radiation beam B for EUV lithography. In general, the EUV source can be configured in a radiation source SO, and a corresponding illumination system IL can be configured to condition the EUV radiation beam B of the EUV source.

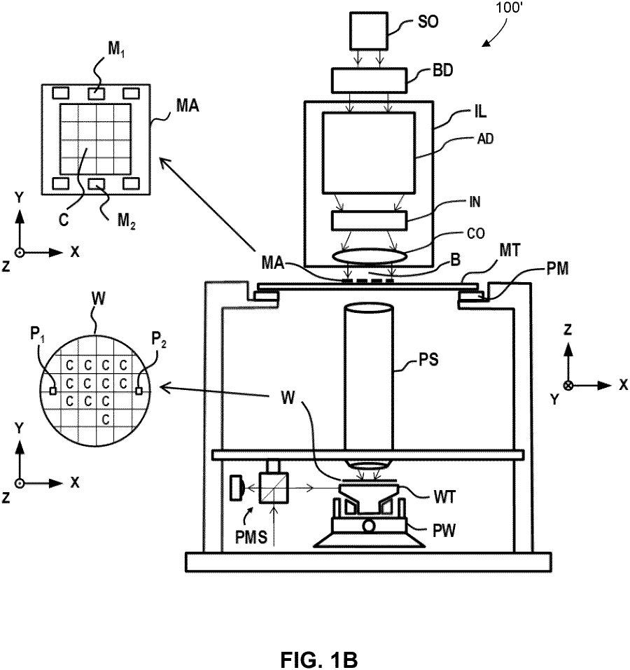

FIG. 2 shows the lithographic apparatus 100 in more detail, including the radiation source SO (e.g., a source collector apparatus), the illumination system IL, and the projection system PS. As shown in FIG. 2, the lithographic apparatus 100 is illustrated from a point of view (e.g., a side view) that is normal to the XZ plane (e.g., the X-axis points to the right and the Z-axis points upward).

The radiation source SO is constructed and arranged such that a vacuum environment can be maintained in an enclosing structure 220. The radiation source SO includes a source chamber 211 and a collector chamber 212 and is configured to produce and transmit EUV radiation. EUV radiation can be produced by a gas or vapor, for example xenon (Xe) gas, lithium (Li) vapor, or tin (Sn) vapor in which an EUV radiation emitting plasma 210 is created to emit radiation in the EUV range of the electromagnetic spectrum. The EUV radiation emitting plasma 210, at least partially ionized, can be created by, for example, an electrical discharge or a laser beam. Partial pressures of, for example, about 10.0 pascals (Pa) of Xe gas, Li vapor, Sn vapor, or any other suitable gas or vapor can be used for efficient generation of the radiation. In some aspects, a plasma of excited tin is provided to produce EUV radiation.

The radiation emitted by the EUV radiation emitting plasma 210 is passed from the source chamber 211 into the collector chamber 212 via an optional gas barrier or contaminant trap 230 (e.g., in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap 230 further indicated herein at least includes a channel structure.

The collector chamber 212 can include a radiation collector CO (e.g., a condenser or collector optic), which can be a so-called grazing incidence collector. Radiation collector CO has an upstream radiation collector side 251 and a downstream radiation collector side 252. Radiation that traverses radiation collector CO can be reflected off a grating spectral filter 240 to be focused in a virtual source point IF. The virtual source point IF is commonly referred to as the intermediate focus, and the source collector apparatus is arranged such that the virtual source point IF is located at or near an opening 219 in the enclosing structure 220. The virtual source point IF is an image of the EUV radiation emitting plasma 210. Grating spectral filter 240 is used in particular for suppressing infrared (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the radiation beam 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination system IL and projection system PS. Optionally, the grating spectral filter 240 can be present depending upon the type of lithographic apparatus. Further, there can be more mirrors present than those shown in the FIG. 2. For example, there can be one to six additional reflective elements present in the projection system PS than shown in FIG. 2.

Radiation collector CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a radiation collector CO of this type is preferably used in combination with a discharge produced plasma (DPP) source.

### Example Lithographic Cell

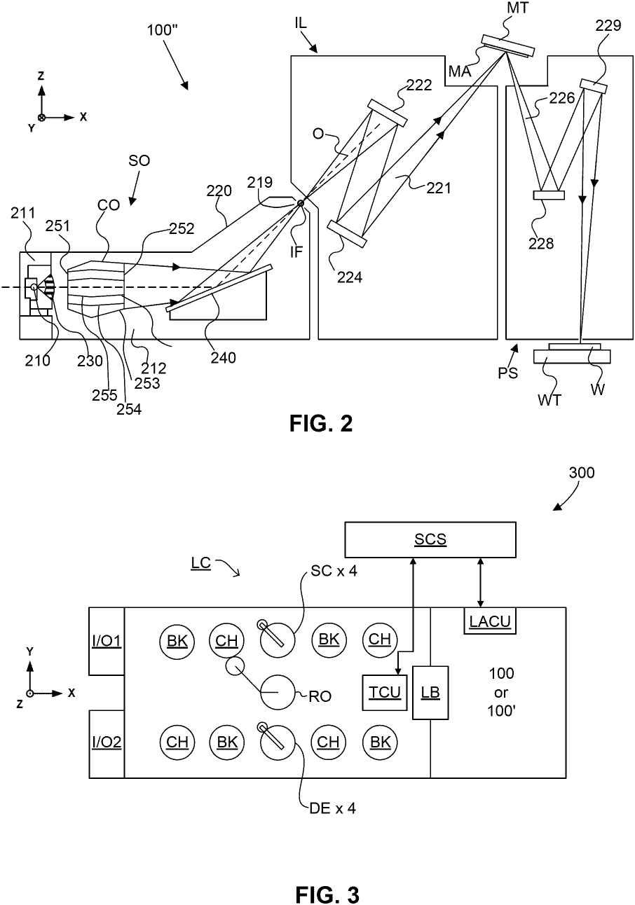

FIG. 3 shows a lithographic cell 300, also sometimes referred to a lithocell or cluster. As shown in FIG. 3, the lithographic cell 300 is illustrated from a point of view (e.g., a top view) that is normal to the XY plane (e.g., the X-axis points to the right and the Y-axis points upward).

Lithographic apparatus 100 or 100′ can form part of lithographic cell 300. Lithographic cell 300 can also include one or more apparatuses to perform pre- and post-exposure processes on a substrate. For example, these apparatuses can include spin coaters SC to deposit resist layers, developers DE to develop exposed resist, chill plates CH, and bake plates BK. A substrate handler RO (e.g., a robot) picks up substrates from input/output ports I/O1 and I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Radiation Source

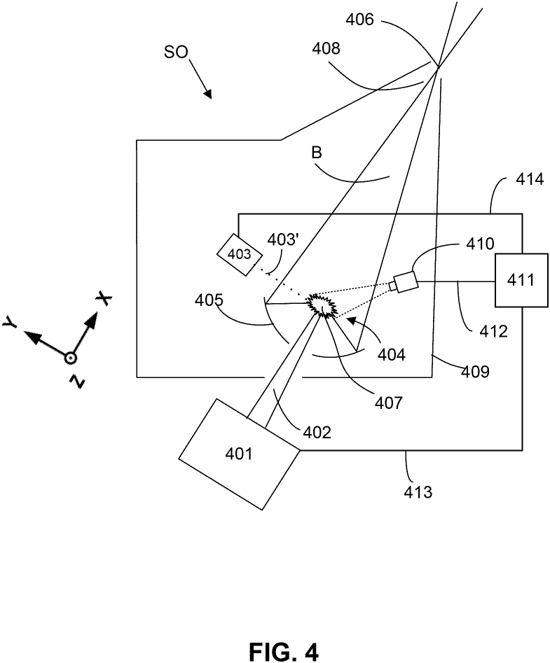

An example of the radiation source SO for an example reflective lithographic apparatus (e.g., lithographic apparatus 100 of FIG. 1A) is shown in FIG. 4. As shown in FIG. 4, the radiation source SO is illustrated from a point of view (e.g., a top view) that is normal to the XY plane as described below.

The radiation source SO shown in FIG. 4 is of a type which can be referred to as a laser produced plasma (LPP) source. A laser system 401, which can for example include a carbon dioxide (CO₂) laser, is arranged to deposit energy via one or more laser beams 402 into fuel targets 403′, such as one or more discrete tin (Sn) droplets, which are provided from a fuel target generator 403 (e.g., example, fuel emitter, droplet generator). According to some aspects, laser system 401 can be, or can operate in the fashion of, a pulsed, continuous wave or quasi-continuous wave laser. The trajectory of fuel targets 403′ (e.g., example, droplets) emitted from the fuel target generator 403 can be parallel to an X-axis. According to some aspects, the one or more laser beams 402 propagate in a direction parallel to a Y-axis, which is perpendicular to the X-axis. A Z-axis is perpendicular to both the X-axis and the Y-axis and extends generally into (or out of) the plane of the page, but in other aspects, other configurations are used. In some embodiments, the laser beams 402 can propagate in a direction other than parallel to the Y-axis (e.g., in a direction other than orthogonal to the X-axis direction of the trajectory of the fuel targets 403′).

Although tin is referred to in the following description, any suitable target material can be used. The target material can for example be in liquid form, and can for example be a metal or alloy. Fuel target generator 403 can include a nozzle configured to direct tin, e.g., in the form of fuel targets 403′ (e.g., discrete droplets) along a trajectory towards a plasma formation region 404. Throughout the remainder of the description, references to “fuel”, “fuel target” or “fuel droplet” are to be understood as referring to the target material (e.g., droplets) emitted by fuel target generator 403. Fuel target generator 403 can include a fuel emitter. The one or more laser beams 402 are incident upon the target material (e.g., tin) at the plasma formation region 404. The deposition of laser energy into the target material creates a plasma 407 at the plasma formation region 404. Radiation, including EUV radiation, is emitted from the plasma 407 during de-excitation and recombination of ions and electrons of the plasma.

The EUV radiation is collected and focused by a radiation collector 405 (e.g., radiation collector CO). In some aspects, radiation collector 405 can include a near normal-incidence radiation collector (sometimes referred to more generally as a normal-incidence radiation collector). The radiation collector 405 can be a multilayer structure, which is arranged to reflect EUV radiation (e.g., EUV radiation having a desired wavelength such as about 13.5 nm). According to some aspects, radiation collector 405 can have an ellipsoidal configuration, having two focal points. A first focal point can be at the plasma formation region 404, and a second focal point can be at an intermediate focus 406, as discussed herein.

In some aspects, laser system 401 can be located at a relatively long distance from the radiation source SO. Where this is the case, the one or more laser beams 402 can be passed from laser system 401 to the radiation source SO with the aid of a beam delivery system (not shown) including, for example, suitable directing mirrors and/or a beam expander, and/or other optics. Laser system 401 and the radiation source SO can together be considered to be a radiation system.

Radiation that is reflected by radiation collector 405 forms a radiation beam B. The radiation beam B is focused at a point (e.g., the intermediate focus 406) to form an image of plasma formation region 404, which acts as a virtual radiation source for the illumination system IL. The point at which the radiation beam B is focused can be referred to as the intermediate focus (IF) (e.g., intermediate focus 406). The radiation source SO is arranged such that the intermediate focus 406 is located at or near to an opening 408 in an enclosing structure 409 of the radiation source SO.

The radiation beam B passes from the radiation source SO into the illumination system IL, which is configured to condition the radiation beam B. The radiation beam B passes from the illumination system IL and is incident upon the patterning device MA held by the support structure MT. The patterning device MA reflects and patterns the radiation beam B. Following reflection from the patterning device MA the patterned radiation beam B enters the projection system PS. The projection system includes a plurality of mirrors, which are configured to project the radiation beam B onto a substrate W held by the substrate table WT. The projection system PS can apply a reduction factor to the radiation beam, forming an image with features that are smaller than corresponding features on the patterning device MA. For example, a reduction factor of four can be applied. Although the projection system PS is shown as having two mirrors in FIG. 2, the projection system can include any number of mirrors (e.g., six mirrors).

The radiation source SO can also include components which are not illustrated in FIG. 4. For example, a spectral filter can be provided in the radiation source SO. The spectral filter can be substantially transmissive for EUV radiation but substantially blocking for other wavelengths of radiation such as infrared radiation.

The radiation source SO (or radiation system) can further include a fuel target sensing system to obtain sensing data (e.g., images, other data or electronic signals, or a combination thereof) associated with fuel targets (e.g., droplets) in the plasma formation region 404 or, more particularly, to obtain sensing data associated with shadows of the fuel targets. The fuel target sensing system can detect radiation (e.g., light) diffracted from the edges of the fuel targets. References to sensing data associated with the fuel targets in the following text should be understood also to refer to sensing data associated with shadows of the fuel targets or diffraction patterns caused by the fuel targets.

The fuel target sensing system can include one or more optical sensing devices including, but not limited to, one or more photoreceivers (e.g., quad-cells), imaging devices (e.g., photosensors, photodetectors, photodiodes, cameras, DFCs, charge-coupled device (CCD) arrays, complementary metal-oxide-semiconductor (CMOS) sensors, or other suitable devices), position sensors (e.g., laser beam position and power sensing detectors, thermopile position and power sensors), optical components (e.g., lenses, mirrors, beam splitters, optical filters, wave plates, wave guides, optical fibers, or other suitable components), or combinations thereof.

In some aspects, the fuel target sensing system can include: a first optical sensing device that includes a photoreceiver configured to generate first sensing data at a first rate; and a second optical sensing device that includes an imaging device configured to generate second sensing data at a second rate. In some aspects, the second rate can be different from the first rate. For example, the first rate can be about 50 kHz and the second rate can be about 5 Hz.

In some aspects, the fuel target sensing system can include: a first optical sensing device that includes a first DFC configured to generate first sensing data at a first rate; and a second optical sensing device that includes a second DFC configured to be synchronized to the first DFC and to generate second sensing data at a second rate. In some aspects, the second rate can be about equal to the first rate. For example, each of the first rate and the second rate can be about equal to 5 Hz.

In one illustrative example, the fuel target sensing system can include a camera 410, e.g., a combination of an imaging device and one or more optical components. The optical components can be selected so that the photosensor or camera 410 obtains near-field images, far-field images, or both. The camera 410 can be positioned within the radiation source SO at any appropriate location from which the camera has a line of sight to the plasma formation region 404 and one or more markers (not shown in FIG. 4) provided on the radiation collector 405. In some aspects, however, it can be necessary to position the camera 410 away from the propagation path of the one or more laser beams 402 and from the trajectory of the fuel targets emitted from fuel target generator 403 so as to avoid damage to the camera 410. According to some aspects, the camera 410 is configured to provide images of the fuel targets to a controller 411 via a connection 412. The connection 412 is shown as a wired connection, though it will be appreciated that the connection 412 (and other connections referred to herein) can be implemented as either a wired connection or a wireless connection or a combination thereof.

As shown in FIG. 4, the radiation source SO can include a fuel target generator 403 configured to generate and emit fuel targets 403′ (e.g., discrete tin droplets) towards a plasma formation region 404. The radiation source SO can further include a laser system 401 configured to hit one or more of the fuel targets 403′ with one or more laser beams 402 for generating a plasma 407 at the plasma formation region 404. The radiation source SO can further include a radiation collector 405 (e.g., a radiation collector CO) configured to collect radiation emitted by the plasma 407.

### Example L2D Alignment System

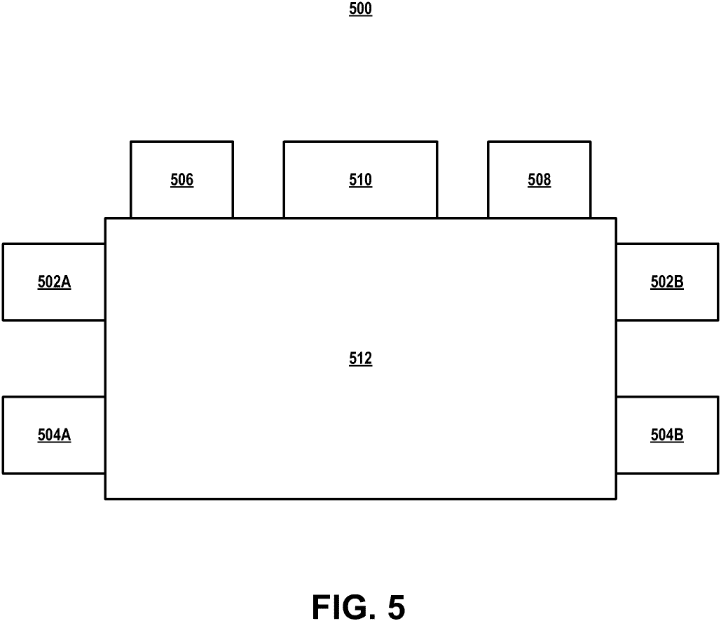

FIG. 5 is a schematic illustration of an example L2D alignment system 500 including example structures and components that can be mechanically connected (e.g., anchored or otherwise attached by one or more fasteners, clamps, adhesives, or a combination thereof) to an example enclosing structure 512 (e.g., enclosing structure 220, enclosing structure 409) of an example radiation source SO according to some aspects of the present disclosure. As shown in FIG. 5, the example L2D alignment system 500 can include first optical sensing device 502A, second optical sensing device 502B, first illumination device 504A, second illumination device 504B, laser-to-droplet (L2D) alignment controller 510, laser steering system 506, fuel target steering system 508, any other suitable component, or any combination thereof.

In some aspects, the example L2D alignment system 500 can include a first optical sensing device 502A configured to generate, at a first rate, first sensing data indicative of a first overlap between a fuel target (e.g., one of the fuel targets 403′) and a laser beam (e.g., one of the one or more laser beams 402, such as a pre-pulse laser beam) obtained from a first angle at about a time that the laser beam is generated. In some aspects, the example L2D alignment system 500 can further include a second optical sensing device 502B configured to generate, at a second rate, second sensing data indicative of a second overlap between the fuel target and the laser beam obtained from a second angle different from the first angle at about the time that the laser beam is generated.

In some aspects, the first optical sensing device 502A can include a photoreceiver (e.g., a quad-cell) configured to generate first sensing data (e.g., quad-cell data) at a first rate (e.g., a faster refresh rate such as 50 kHz). In some aspects, the second optical sensing device 502B can include an imaging device (e.g., a camera) configured to generate second sensing data (e.g., image data) at a second rate (e.g., a slower refresh rate such as 5 Hz). In some aspects, the second rate can be less than the first rate.

In some aspects, the first optical sensing device 502A can include a first DFC. In some aspects, the second optical sensing device 502B can include a second DFC configured to be synchronized to the first DFC. In some aspects, the second rate can be about equal to the first rate. In some aspects, the third rate can be about equal to the first rate. For example, each of the first rate and the second rate can be about equal to 5 Hz.

In some aspects, the example L2D alignment system 500 can further include a first illumination device 504A configured to illuminate the fuel target from a first illumination angle at about the time that the laser beam is generated. In some aspects, the example L2D alignment system 500 can further include a second illumination device 504B configured to illuminate the fuel target from a second illumination angle different from the first illumination angle at about the time that the laser beam is generated. In some aspects, the first illumination device 504A can include a first backlight laser module (BLM). In some aspects, the second illumination device 504B can include a second BLM configured to be synchronized to the first BLM.

In some aspects, the example L2D alignment system 500 can further include a fuel target sensing system. In some aspects, the fuel target sensing system can include the first optical sensing device 502A (e.g., implemented as a photoreceiver) and the second optical sensing device 502B (e.g., implemented as an imaging device) and can be configured to detect an overlap between the one or more laser beams 402 and the fuel targets 403′. In other aspects, the fuel target sensing system can include a dual DFC system configured to detect an overlap between the one or more laser beams 402 and the fuel targets 403′. The dual DFC system can include the first optical sensing device 502A (e.g., implemented as a first DFC), the second optical sensing device 502B (e.g., implemented as a second DFC), the first illumination device 504A (e.g., a first BLM), the second illumination device 504B (e.g., a second BLM), any other suitable component, or any combination thereof.

In some aspects, the one or more laser beams 402 can include a pre-pulse laser beam and a main pulse laser beam. In some aspects, the laser system 401 can be configured to hit each of the fuel targets 403′ with a pre-pulse laser beam to generate a modified fuel target. In some aspects, the dual DFC system can be configured to trigger each of the first optical sensing device 502A, the second optical sensing device 502B, the first illumination device 504A, and the second illumination device 504B based on about a time when the pre-pulse laser beam is created. In some aspects, the laser system 401 can be further configured to hit each of the modified fuel targets with a main pulse laser beam to generate the plasma 407.

In some aspects, the example L2D alignment system 500 can further include a laser steering system 506 configured to monitor and steer the one or more laser beams 402 towards the plasma formation region 404. In some aspects, the laser steering system 506 can include a laser steering actuator configured to steer the one or more laser beams 402 towards the plasma formation region 404. In some aspects, the laser steering system 506 can further include a laser steering metrology system configured to monitor the one or more laser beams 402. In some aspects, the laser steering actuator can be configured to receive (e.g., from the L2D alignment controller 510 or the laser steering metrology system) a laser steering control signal indicative of an electronic instruction to steer the one or more laser beams 402 towards the plasma generation region 404. In some aspects, the laser steering actuator can be further configured to steer the one or more laser beams 402 towards the plasma generation region 404 based on the laser steering control signal.

In some aspects, the example L2D alignment system 500 can further include a fuel target steering system 508 configured to monitor and steer the fuel targets 403′ towards the plasma formation region 404. In some aspects, the fuel target steering system 508 can include a fuel target steering actuator configured to steer the fuel targets 403′ towards the plasma formation region 404. In some aspects, the fuel target steering system 508 can further include a fuel target steering metrology system configured to monitor the fuel targets 403′. In some aspects, the fuel target steering actuator can be configured to receive (e.g., from the L2D alignment controller 510 or the fuel target steering metrology system) a fuel target steering control signal indicative of an electronic instruction to steer the fuel targets 403′ towards the plasma generation region 404. In some aspects, the fuel target steering actuator can be further configured to steer the fuel targets 403′ towards the plasma generation region 404 based on the fuel target steering control signal.

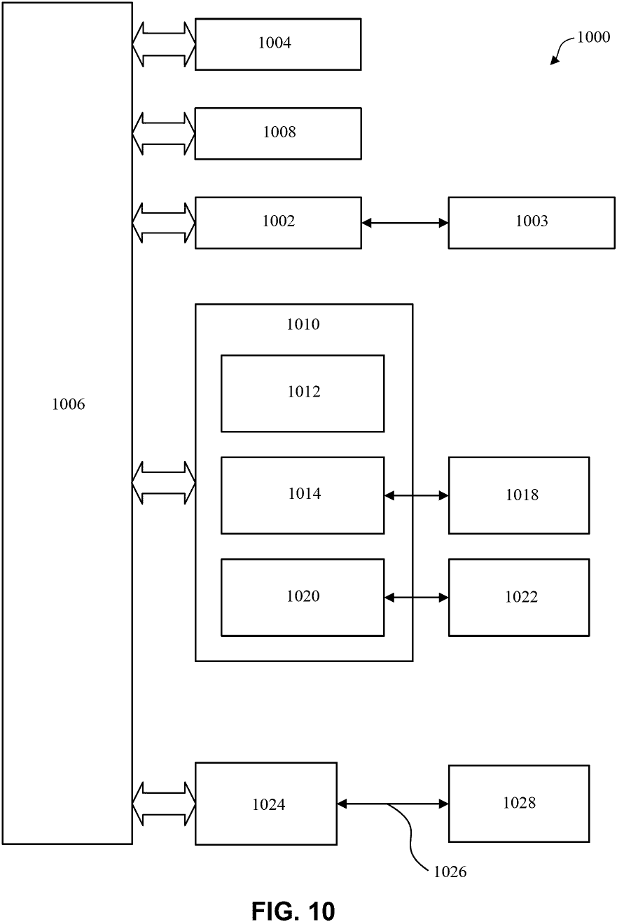

In some aspects, the example L2D alignment system 500 can further include an L2D alignment controller 510. In some aspects, the controller can include one or more of the structures and features described with reference to controller 411 shown in FIG. 4, the fuel target steering system described with reference to FIG. 4, example computing system 1000 shown in FIG. 10, any other suitable controller or computing system, or any combination thereof. In some aspects, the L2D alignment controller 510 can be configured to receive (e.g., directly or indirectly; raw, pre-processed, or processed) the first sensing data from the first optical sensing device 502A at a first rate. In some aspects, the L2D alignment controller 510 can be further configured to receive the second sensing data from the second optical sensing device 502B at a second rate. In some aspects, the L2D alignment controller 510 can be further configured to generate, at a third rate, stereoscopic sensing data based on the first sensing data and the second sensing data. In some aspects (e.g., in a configuration that includes a photoreceiver having a faster refresh rate and an imaging device having a slower refresh rate), the second rate can be different from the first rate, and the third rate can be about equal to the first rate. In other aspects (e.g., in a configuration that includes two imaging devices having about the same refresh rate), the first rate and the second rate can be about equal to the third rate.

In some aspects, the L2D alignment controller 510 can be further configured to generate fuel target data based on the first sensing data and the second sensing data. The fuel target data can be indicative of a set of properties of the fuel target (e.g., detected, measured, captured, obtained, or actual properties associated with one or more of the fuel targets 403′). In some aspects, the fuel target data can include laser-to-droplet (L2D) data. The L2D data can include, for example, one or more values or other data indicative of the difference (e.g., magnitude, direction) between the fuel target and a center of mass of the pre-pulse laser beam. For example, the L2D data can include: L2D_X data indicative of the difference (e.g., magnitude, direction) between the fuel target and the center of mass of the pre-pulse laser beam along the X-axis; L2D_Y data indicative of the difference (e.g., magnitude, direction) between the fuel target and the center of mass of the pre-pulse laser beam along the Y-axis; L2D_Z data indicative of the difference (e.g., magnitude, direction) between the fuel target and the center of mass of the pre-pulse laser beam along the Z-axis; any other suitable value or data; and any combination thereof. In some aspects, the L2D alignment controller 510 can be further configured to generate the fuel target data based on stereoscopic sensing data generated based on the first sensing data and the second sensing data.

In some aspects, the L2D alignment controller 510 can be further configured to generate, based on the fuel target data, a steering control signal configured to steer the laser beam, the fuel target, or both. In some aspects, the steering control signal can include a laser steering control signal indicative of an electronic instruction to steer the laser beam towards a plasma generation region. In some aspects, the steering control signal can include a fuel target steering control signal indicative of an electronic instruction to steer the fuel target towards a plasma generation region. In some aspects, the steering control signal can include: a laser steering control signal indicative of a first electronic instruction to steer the laser beam; and a fuel target steering control signal indicative of a second electronic instruction to steer the fuel target. In some aspects, the L2D alignment controller 510 can be further configured to transmit the laser steering control signal to the laser steering system 506. In some aspects, the laser steering actuator of the laser steering system 506 can be configured to receive the laser steering control signal and steer the laser beam towards the plasma generation region based on the laser steering control signal. In some aspects, the L2D alignment controller 510 can be configured to transmit the fuel target steering control signal to the fuel target steering system 508. In some aspects, the fuel target steering actuator of the fuel target steering system 508 can be configured to receive the fuel target steering control signal and steer the fuel target towards the plasma generation region based on the fuel target steering control signal.

In some aspects, the L2D alignment controller 510 can be further configured to generate the steering control signal based on estimated fuel target data rather than directly from the fuel target data. For example, the L2D alignment controller 510 can be further configured to generate estimated fuel target data, refine the estimated fuel target data based on the fuel target data measured by the dual DFC system (e.g., using a feedback controller, state observer, proportional-integral-derivative (PID) controller, Kalman filter), and then generate the steering control signal based on the refined estimated fuel target data.

In some aspects, the L2D alignment controller 510 can be further configured to generate first estimated fuel target data. The first estimated fuel target data can be indicative of a first set of estimated properties of the fuel target. In some aspects, the L2D alignment controller 510 can be further configured to generate a comparison of the fuel target data and the first estimated fuel target data. In some aspects, the L2D alignment controller 510 can be further configured to generate fuel target estimation error data based on the comparison.

In some aspects, the L2D alignment controller 510 can be further configured to generate second estimated fuel target data based on the fuel target data, the first estimated fuel target data, and the fuel target estimation error data. The second estimated fuel target data can be indicative of a second set of estimated properties of the fuel target.

In some aspects, where the steering control signal is a first steering control signal, the L2D alignment controller 510 can be further configured to: generate, at a first time, the first steering control signal based on the fuel target data; and generate, at a second time different from the first time, a second steering control signal based on the second estimated fuel target data. In some aspects, where the comparison is a first comparison and the fuel target estimation error data is first fuel target estimation error data, the L2D alignment controller 510 can be further configured to: generate a second comparison of the fuel target data and the second estimated fuel target data; and generate second fuel target estimation error data based on the second comparison. The second fuel target estimation error data can indicate an absence of an error between the fuel target data and the second estimated fuel target data. For example, the L2D alignment controller 510 can be configured to determine that the error between the fuel target data and the second estimated fuel target data is below an error tolerance value (e.g., +/-0.1 percent, +/- 2 percent, or any other suitable value or range), and in response to the determination, determine that the second fuel target estimation error data indicates an absence of an error between the fuel target data and the second estimated fuel target data.

In some aspects, the L2D alignment controller 510 can be configured to calibrate a reference point of the fuel target steering system 508 such that each of the fuel targets 403′ generated by the fuel target generator 403 is positioned at about a center of a field of view of the fuel target sensing system (e.g., the dual DFC system).

In one example, the fuel target steering system 508 can include a coarse fuel target steering system, a fine fuel target steering system, and a nozzle steering system. In this example, to calibrate the reference point of the fuel target steering system 508, the L2D alignment controller 510 can be configured to control the nozzle steering system to steer the fuel targets 403′ to about a center of a field of view of the coarse fuel target steering system and a center of a field of view of the fine fuel target steering system. In another example, the reference point of the fuel target steering system can be a first reference point, the laser steering system 506 can include a pre-pulse laser steering system, and the L2D alignment controller 510 can be further configured to calibrate a second reference point of the pre-pulse laser steering system using the first reference point of the fuel target steering system 508. In this example, the laser steering system 506 can include a main pulse laser steering system, and the L2D alignment controller 510 can be further configured to use the main pulse laser steering system to measure a main pulse position relative to a pre-pulse position to estimate the main pulse location relative to each of the fuel targets 403′.

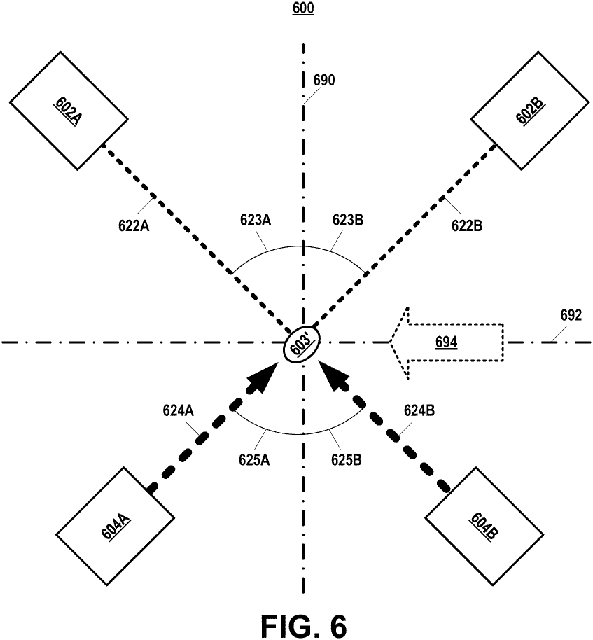

FIG. 6 is a schematic illustration of an example fuel target sensing system 600 according to some aspects of the present disclosure. As shown in FIG. 6, the example fuel target sensing system 600 can include a first optical sensing device 602A, a second optical sensing device 602B, a first illumination device 604A, and a second illumination device 604B. In some aspects, the first optical sensing device 602A, second optical sensing device 602B, first illumination device 604A, and the second illumination device 604B, can include any of the features and structures described with reference to first optical sensing device 502A, second optical sensing device 502B, first illumination device 504A, and second illumination device 504B, respectively, described with reference to FIG. 5. In some aspects, the example fuel target sensing system 600 can further include an L2D alignment controller (e.g., L2D alignment controller 510), a laser steering system (e.g., laser steering system 506), a fuel target steering system (e.g., fuel target steering system 508, any other suitable component, or any combination thereof.

In some aspects, the fuel target sensing system 600 can include the first optical sensing device 602A (e.g., implemented as a photoreceiver), the second optical sensing device 602B (e.g., implemented as an imaging device), any other suitable component, or any combination thereof. In other aspects, the fuel target sensing system 600 can include a dual DFC system that includes the first optical sensing device 602A (e.g., implemented as a first DFC), the second optical sensing device 602B (e.g., implemented as a second DFC), the first illumination device 604A (e.g., a first BLM), the second illumination device 604B (e.g., a second BLM), any other suitable component, or any combination thereof.

In some aspects, the first optical sensing device 602A can be configured to generate first sensing data indicative of a first overlap between a fuel target 603′ (e.g., generated by fuel target generator 403 and traveling in the direction indicated by arrow 694) and a laser beam (e.g., a pre-pulse laser beam generated by the laser system 401) obtained from a first angle 623A (e.g., along a first axis 622A) at about a time that the laser beam is generated (e.g., at about a time that the laser system 401 hits the fuel target 603′ with a pre-pulse laser beam to generate a modified fuel target).

In some aspects, the second optical sensing device 602B can be configured to generate second sensing data indicative of a second overlap between the fuel target 603′ and the laser beam obtained from a second angle 623B (e.g., along a second axis 622B) different (e.g., in orientation, magnitude, or both) from the first angle 623A at about the time that the laser beam is generated. For example, the second optical sensing device 602B can be disposed in a first quadrant (e.g., the top-right quadrant, also referred to as “Quadrant I”) of the plane defined by the orthogonal axes 690 and 692, and the second optical sensing angle 623B can be disposed 45 degrees clockwise from the axis 690. In another example, the first optical sensing device 602A can be disposed in a second quadrant (e.g., the top-left quadrant, also referred to as “Quadrant II”) of the plane defined by the orthogonal axes 690 and 692, and the first angle 623A can be disposed 45 degrees counterclockwise from the axis 690.

In some aspects, the first optical sensing device 602A can include a first DFC. In some aspects, the second optical sensing device 602B can include a second DFC configured to be synchronized to the first DFC.

In some aspects, the first optical sensing device 602A can include a photoreceiver (e.g., a quad-cell) configured to generate first sensing data (e.g., quad-cell data) at a first rate (e.g., a faster refresh rate such as 50 kHz). In some aspects, the second optical sensing device 602B can include an imaging device (e.g., a camera) configured to generate second sensing data (e.g., image data) at a second rate (e.g., a slower refresh rate such as 5 Hz). In some aspects, the second rate can be less than the first rate.

In some aspects, the first optical sensing device 602A can include a first DFC. In some aspects, the second optical sensing device 602B can include a second DFC configured to be synchronized to the first DFC. In some aspects, the second rate can be about equal to the first rate. In some aspects, the third rate can be about equal to the first rate. For example, each of the first rate and the second rate can be about equal to 5 Hz.

In some aspects, the first illumination device 604A can be configured to generate a first radiation beam 624A configured to illuminate the fuel target 603′ from a first illumination angle 625A at about the time that the laser beam is generated. In some aspects, the second illumination device 604B can be configured to generate a second radiation beam 624B configured to illuminate the fuel target 603′ from a second illumination angle 625B different (e.g., in orientation, magnitude, or both) from the first illumination angle at about the time that the laser beam is generated. For example, the first illumination device 604A can be disposed in a third quadrant (e.g., the bottom-left quadrant, also referred to as “Quadrant III”) of the plane defined by the orthogonal axes 690 and 692, and the first illumination angle 625A can be disposed 45 degrees clockwise from the axis 690. In another example, the second illumination device 604B can be disposed in a fourth quadrant (e.g., the bottom-right quadrant, also referred to as “Quadrant IV”) of the plane defined by the orthogonal axes 690 and 692, and the second illumination angle 625B can be disposed 45 degrees counterclockwise from the axis 690. In some aspects, the first illumination device 604A can include a first BLM. In some aspects, the second illumination device 604B can include a second BLM configured to be synchronized to the first BLM.

In some aspects, the example fuel target sensing system 600 can be configured to trigger each of the first optical sensing device 602A, the second optical sensing device 602B, the first illumination device 604A, and the second illumination device 604B based on about a time when the pre-pulse laser beam is created (e.g., by the laser system 401).

FIG. 7 is a schematic illustration of an example L2D alignment process 700 according to some aspects of the present disclosure. The operations described with reference to the example L2D alignment process 700 can be performed by, or according to, any of the systems, apparatuses, components, structures, features, techniques, or combinations thereof described herein, such as those described with reference to FIGS. 1-6 above and FIGS. 8-10 below.

At block 702, a fuel target sensing system (e.g., fuel target sensing system 600; the fuel target sensing system described with reference to the example L2D alignment system 500) generates first sensing data and second sensing data. At block 704, a controller (e.g., controller 411, L2D alignment controller 510; example computing system 1000) receives the first sensing data and the second sensing data along communications path 703 and generates stereoscopic sensing data based on the first sensing data and the second sensing data. The controller then generates measured fuel target data indicative of set of measured fuel target properties based on the stereoscopic sensing data. The controller transmits the measured fuel target data along communications path 705.

At block 706, the controller generates first estimated fuel target data indicative of a first set of estimated properties of the fuel target. The controller transmits the first estimated fuel target data along communications path 707. At block 708, the controller generates a first comparison of the measured fuel target and the first estimated fuel target data. The controller transmits the first comparison along communications path 709. At block 710, the controller generates first fuel target estimation error data based on the first comparison and, in some instances, by updating the Kalman gain. The controller transmits the first fuel target estimation error data along the communications path 711.

Returning to block 706, the controller generates second estimated fuel target data based on the first fuel target estimation error data. The second estimated fuel target data can be indicative of a second set of estimated properties of the fuel target. At block 708, the controller generates a second comparison of the measured fuel target data and the second estimated fuel target data. At block 710, the controller generates second fuel target estimation error data based on the second comparison.

Returning again to block 706, in response to a determination by the controller that the error between the measured fuel target data and the second estimated fuel target data is below an error tolerance value (e.g., +/- 0.1 percent, +/- 2 percent, or any other suitable value or range), the controller determines that the second fuel target estimation error data indicates an absence of an error between the measured fuel target data and the second estimated fuel target data. As a result, the controller outputs the second estimated fuel target data along communications path 713 for use in generating, by the controller, a steering control signal configured to steer the laser beam, the fuel target, or both.

FIG. 8 shows a set of example graphs 800 associated with the example L2D alignment process 700 described with reference to FIG. 7. As shown in FIG. 8, the set of example graphs 800 includes a first graph 810 showing L2D_X data over time, where the L2D_X data is indicative of the difference (e.g., magnitude, direction) between the fuel target and the center of mass of the pre-pulse laser beam along the X-axis. The L2D_X data is shown for measured L2D_X data 812 (e.g., “measured”; measured fuel target data), estimated L2D_X data 814 (e.g., “estimate”; second estimated fuel target data), and expected L2D_X data 816 (e.g., “real”; designed or expected fuel target data).

As further shown in FIG. 8, the set of example graphs 800 includes a second graph 820 showing L2D_Y data over time, where the L2D_Y data is indicative of the difference (e.g., magnitude, direction) between the fuel target and the center of mass of the pre-pulse laser beam along the Y-axis. The L2D_Y data is shown for measured L2D_Y data 822 (e.g., “measured”; measured fuel target data), estimated L2D_Y data 824 (e.g., “estimate”; second estimated fuel target data), and expected L2D_Y data 826 (e.g., “real”; designed or expected fuel target data).

As shown in the first graph 810 and the second graph 820, the estimated fuel target data (e.g., estimated L2D_X data 814, estimated L2D_Y data 824) includes substantially less noise than the measured fuel target data (e.g., measured L2D_X data 812, measured L2D_Y data 822). Accordingly, the controller can improve the accuracy, speed, and performance of the L2D alignment system disclosed herein by generating the steering control signal described herein based on the estimated fuel target data rather than the measured fuel target data alone.

### Example Processes for Aligning a Laser Beam and a Fuel Target

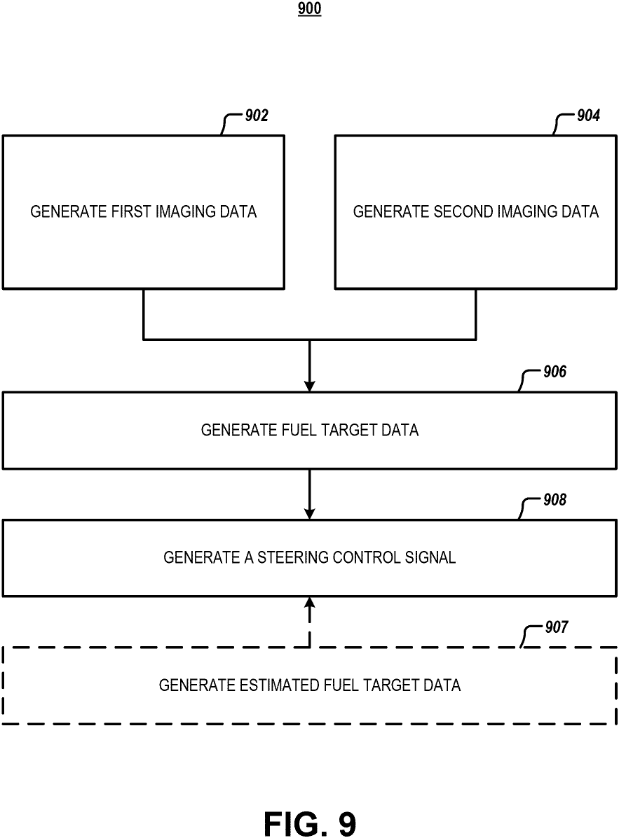

FIG. 9 is an example method 900 for aligning a laser beam and a fuel target according to some aspects of the present disclosure or portion(s) thereof. The operations described with reference to example method 900 can be performed by, or according to, any of the systems, apparatuses, components, techniques, or combinations thereof described herein, such as those described with reference to FIGS. 1-8 above and FIG. 10 below.

At operation 902, the method can include generating, by a first optical sensing device (e.g., first optical sensing device 502A, first optical sensing device 602A) at a first rate, first sensing data indicative of a first overlap between a fuel target (e.g., one of fuel targets 403′, fuel target 603′) and a laser beam (e.g., one of the one or more laser beams 402, such as a pre-pulse laser beam). In some aspects, the generation of the first sensing data can be accomplished using suitable mechanical or other methods and include generating the first sensing data in accordance with any aspect or combination of aspects described with reference to FIGS. 1-8 above and FIG. 10 below.

At operation 904, the method can include generating, by a second optical sensing device (e.g., second optical sensing device 502B, second optical sensing device 602B) at a second rate, second sensing data indicative of a second overlap between the fuel target and the laser beam. In some aspects, the generation of the second sensing data can be accomplished using suitable mechanical or other methods and include generating the second sensing data in accordance with any aspect or combination of aspects described with reference to FIGS. 1-8 above and FIG. 10 below.

At operation 906, the method can include generating, by a controller (e.g., controller 411 described with reference to FIG. 4; L2D alignment controller 510 shown in FIG. 5, example computing system 1000 shown in FIG. 10), fuel target data based on the first sensing data and the second sensing data. In some aspects, the generation of the fuel target data can be accomplished using suitable mechanical or other methods and include generating the fuel target data in accordance with any aspect or combination of aspects described with reference to FIGS. 1-8 above and FIG. 10 below.

Optionally, at operation 907, the method can include generating, by the controller, estimated fuel target data. In some aspects, the generation of the estimated fuel target data can be accomplished using suitable mechanical or other methods and include generating the estimated fuel target data in accordance with any aspect or combination of aspects described with reference to FIGS. 1-8 above and FIG. 10 below.

At operation 908, the method can include generating, by the controller at a third rate, a steering control signal configured to steer the laser beam or the fuel target. In some aspects, the generating the steering control signal can include generating, by the controller, the steering control signal based on the fuel target data, the estimated target data, or both. In some aspects, the generation of the steering control signal can be accomplished using suitable mechanical or other methods and include generating the steering control signal in accordance with any aspect or combination of aspects described with reference to FIGS. 1-8 above and FIG. 10 below.

### Example Computing System

Aspects of the disclosure can be implemented in hardware, firmware, software, or any combination thereof. Aspects of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions, and combinations thereof can be described herein as performing certain actions. However, it should be appreciated that such descriptions are merely for convenience and that such actions in fact result from computing devices, processors, controllers, or other devices executing the firmware, software, routines, instructions, or combinations thereof and, in doing so, causing actuators or other devices (e.g., servo motors, robotic devices) to interact with the physical world.

Various aspects can be implemented, for example, using one or more computing systems, such as example computing system 1000 shown in FIG. 10. Example computing system 1000 can be a specialized computer capable of performing the functions described herein such as: controller 411 described with reference to FIG. 4; the fuel target steering system described with reference to FIG. 4, example L2D alignment system 500, first optical sensing device 502A, second optical sensing device 502B, first illumination device 504A, second illumination device 504B, laser steering system 506 (including, but not limited to, a pre-pulse laser steering system, a main pulse laser steering system, a laser steering actuator, and a laser steering metrology system), fuel target steering system 508 (including, but not limited to, a coarse fuel target steering system, a fine fuel target steering system, a nozzle steering system, a fuel target steering actuator, and a fuel target steering metrology system), or L2D alignment controller 510 described with reference to FIG. 5; example fuel target sensing system 600, first optical sensing device 602A, second optical sensing device 602B, first illumination device 604A, or second illumination device 604B described with reference to FIG. 6; the components described with reference to example L2D alignment process 700 shown in FIG. 7; a fuel target sensing system (including, but not limited to, a system that includes a photoreceiver and an imaging device; or a system that includes two imaging devices, such as a dual DFC system) described with reference to any of FIGS. 4-7; any other suitable system, sub-system, or component; or any combination thereof. Example computing system 1000 can include one or more processors (also called central processing units, or CPUs), such as a processor 1004. Processor 1004 is connected to a communication infrastructure 1006 (e.g., a bus). Example computing system 1000 can also include user input/output device(s) 1003, such as monitors, keyboards, pointing devices, etc., that communicate with communication infrastructure 1006 through user input/output interface(s) 1002. Example computing system 1000 can also include a main memory 1008 (e.g., one or more primary storage devices), such as random access memory (RAM). Main memory 1008 can include one or more levels of cache. Main memory 1008 has stored therein control logic (e.g., computer software) and/or data.

Example computing system 1000 can also include a secondary memory 1010 (e.g., one or more secondary storage devices). Secondary memory 1010 can include, for example, a hard disk drive 1012 and/or a removable storage drive 1014. Removable storage drive 1014 can be a floppy disk drive, a magnetic tape drive, a compact disk drive, an optical storage device, tape backup device, and/or any other storage device/drive.

Removable storage drive 1014 can interact with a removable storage unit 1018. Removable storage unit 1018 includes a computer usable or readable storage device having stored thereon computer software (control logic) and/or data. Removable storage unit 1018 can be a floppy disk, magnetic tape, compact disk, DVD, optical storage disk, and/or any other computer data storage device. Removable storage drive 1014 reads from and/or writes to removable storage unit 1018.

According to some aspects, secondary memory 1010 can include other means, instrumentalities or other approaches for allowing computer programs and/or other instructions and/or data to be accessed by example computing system 1000. Such means, instrumentalities or other approaches can include, for example, a removable storage unit 1022 and an interface 1020. Examples of the removable storage unit 1022 and the interface 1020 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Example computing system 1000 can further include a communications interface 1024 (e.g., one or more network interfaces). Communications interface 1024 enables example computing system 1000 to communicate and interact with any combination of remote devices, remote networks, remote entities, etc. (individually and collectively referred to as remote devices 1028). For example, communications interface 1024 can allow example computing system 1000 to communicate with remote devices 1028 over communications path 1026, which can be wired and/or wireless, and which can include any combination of LANs, WANs, the Internet, etc. Control logic, data, or both can be transmitted to and from example computing system 1000 via communications path 1026.

The operations in the preceding aspects of the present disclosure can be implemented in a wide variety of configurations and architectures. Therefore, some or all of the operations in the preceding aspects can be performed in hardware, in software or both. In some aspects, a tangible, non-transitory apparatus or article of manufacture includes a tangible, non-transitory computer useable or readable medium having control logic (software) stored thereon is also referred to herein as a computer program product or program storage device. This includes, but is not limited to, example computing system 1000, main memory 1008, secondary memory 1010 and removable storage units 1018 and 1022, as well as tangible articles of manufacture embodying any combination of the foregoing. Such control logic, when executed by one or more data processing devices (such as example computing system 1000), causes such data processing devices to operate as described herein.

Based on the teachings contained in this disclosure, it will be apparent to persons skilled in the relevant art(s) how to make and use aspects of the disclosure using data processing devices, computer systems and/or computer architectures other than that shown in FIG. 10. In particular, aspects of the disclosure can operate with software, hardware, and/or operating system implementations other than those described herein.

Although specific reference may be made in this text to the use of lithographic apparatus in the manufacture of ICs, it should be understood that the lithographic apparatuses described herein can have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself can be patterned and materials added on top of it can also be patterned, or can remain without patterning.

The examples disclosed herein are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific aspects of the disclosure have been described above, it will be appreciated that the aspects can be practiced otherwise than as described. The description is not intended to limit the embodiments of the disclosure.

It is to be appreciated that the Detailed Description section, and not the Background, Summary, and Abstract sections, is intended to be used to interpret the claims. The Summary and Abstract sections may set forth one or more but not all example embodiments as contemplated by the inventor(s), and thus, are not intended to limit the present embodiments and the appended claims in any way.

Some aspects of the disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects of the disclosure will so fully reveal the general nature of the aspects that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein.

Other aspects of the invention are set out in the following numbered clauses.

1. A radiation source, comprising:
a first optical sensing device configured to generate, at a first rate, first sensing data indicative of a first overlap between a fuel target and a laser beam;
a second optical sensing device configured to generate, at a second rate, second sensing data indicative of a second overlap between the fuel target and the laser beam; and
a controller configured to:
   receive the first sensing data and the second sensing data;
   generate fuel target data based on the first sensing data and the second sensing data; and
   generate, at a third rate and based on the fuel target data, a steering control signal configured to steer the laser beam or the fuel target.

2. The radiation source of clause 1, wherein:
the first optical sensing device comprises a photoreceiver;
the second optical sensing device comprises an imaging device;
the second rate is different from the first rate; and
the third rate is about equal to the first rate.

3. The radiation source of clause 1, wherein:
the first optical sensing device comprises a first droplet formation camera;
the second optical sensing device comprises a second droplet formation camera configured to be synchronized to the first droplet formation camera;
the second rate is about equal to the first rate; and
the third rate is about equal to the first rate.

4. The radiation source of clause 3, further comprising a dual droplet formation camera system comprising:
the first droplet formation camera, wherein the first sensing data is indicative of the first overlap between the fuel target and the laser beam obtained from a first angle at about a time that the laser beam is generated;
the second droplet formation camera, wherein the second sensing data is indicative of the second overlap between the fuel target and the laser beam obtained from a second angle at about the time that the laser beam is generated;
a first illumination device configured to illuminate the fuel target from a first illumination angle at about the time that the laser beam is generated; and
a second illumination device configured to illuminate the fuel target from a second illumination angle different from the first illumination angle at about the time that the laser beam is generated.

5. The radiation source of clause 4, wherein the laser beam comprises a pre-pulse laser beam.

6. The radiation source of clause 1, wherein the fuel target data comprises laser-to-droplet data.

7. The radiation source of clause 1, wherein the controller is further configured to:
generate stereoscopic sensing data based on the first sensing data and the second sensing data; and
generate the fuel target data based on the stereoscopic sensing data.

8. The radiation source of clause 1, wherein the controller is further configured to:
generate first estimated fuel target data;
generate a comparison of the fuel target data and the first estimated fuel target data;
generate fuel target estimation error data based on the comparison; and
generate second estimated fuel target data based on the fuel target data, the first estimated fuel target data, and the fuel target estimation error data.

9. The radiation source of clause 8, wherein:
the steering control signal is a first steering control signal; and
the controller is further configured to:
   generate, at a first time, the first steering control signal based on the fuel target data; and
   generate, at a second time different from the first time, a second steering control signal based on the second estimated fuel target data.

10. The radiation source of clause 8, wherein:
the comparison is a first comparison;
the fuel target estimation error data is first fuel target estimation error data;
the controller is further configured to:
   generate a second comparison of the fuel target data and the second estimated fuel target data; and
   generate second fuel target estimation error data based on the second comparison; and
   the second fuel target estimation error data indicates an absence of an error between the fuel target data and the second estimated fuel target data.

11. The radiation source of clause 1, further comprising:
a laser steering system, wherein:
the steering control signal comprises a laser steering control signal indicative of an electronic instruction to steer the laser beam towards a plasma generation region; and
the controller is further configured to transmit the laser steering control signal to the laser steering system.

12. The radiation source of clause 11, wherein the laser steering system comprises a laser steering actuator configured to:
receive the laser steering control signal; and
steer the laser beam towards the plasma generation region based on the laser steering control signal.

13. The radiation source of clause 1, further comprising:
a fuel target steering system, wherein:the steering control signal comprises a fuel target steering control signal indicative of an electronic instruction to steer the fuel target towards a plasma generation region; and
the controller is configured to transmit the fuel target steering control signal to the fuel target steering system.

14. The radiation source of clause 13, wherein the fuel target steering system comprises a fuel target steering actuator configured to:
receive the fuel target steering control signal; and
steer the fuel target towards the plasma generation region based on the fuel target steering control signal.

15. The radiation source of clause 1, wherein:
the steering control signal comprises:
a laser steering control signal indicative of a first electronic instruction to steer the laser beam; and
a fuel target steering control signal indicative of a second electronic instruction to steer the fuel target;
the controller is further configured to:
   transmit the laser steering control signal to a laser steering system; and
   transmit the fuel target steering control signal to a fuel target steering system.

16. An apparatus, comprising:
a controller configured to:
   receive first sensing data captured at a first rate and indicative of a first overlap between a fuel target and a laser beam;
   receive second sensing data captured at a second rate and indicative of a second overlap between the fuel target and the laser beam;
   generate fuel target data based on the first sensing data and the second sensing data;
   generate estimated fuel target data;
   generate a comparison of the fuel target data and the estimated fuel target data; generate fuel target estimation error data based on the comparison;
   generate modified estimated fuel target data based on the fuel target data, the estimated fuel target data, and the fuel target estimation error data; and generate, at a third rate and based on the modified estimated target data, a steering control signal configured to steer the laser beam or the fuel target.

17. The apparatus of clause 16, wherein:
the controller is further configured to:
   receive the first sensing data from a first optical sensing device comprising a photoreceiver; and
   receive the second sensing data from a second optical sensing device comprising an imaging device; the second rate is different from the first rate; and
the third rate is about equal to the first rate.

18. The apparatus of clause 16, wherein:
the controller is further configured to:
   receive the first sensing data from a first optical sensing device comprising a first droplet formation camera; and
   receive the second sensing data from a second optical sensing device comprising a second droplet formation camera configured to be synchronized to the first droplet formation camera;
the second rate is about equal to the first rate; and
the third rate is about equal to the first rate.

19. A method comprising:
generating, by a first optical sensing device, first sensing data indicative of a first overlap between a fuel target and a laser beam;
generating, by a second optical sensing device, second sensing data indicative of a second overlap between the fuel target and the laser beam;
generating, by a controller, fuel target data based on the first sensing data and the second sensing data;
generating, by the controller, first estimated fuel target data;
generating, by the controller, a comparison of the fuel target data and the first estimated fuel target data;
generating, by the controller, fuel target estimation error data based on the comparison;
generating, by the controller, second estimated fuel target data based on the fuel target data, the first estimated fuel target data, and the fuel target estimation error data; and
generating, by the controller and based on the second estimated target data, a steering control signal configured to steer the laser beam or the fuel target.

20. The method of clause 19, wherein:
the steering control signal comprises:
   a laser steering control signal indicative of a first electronic instruction to steer the laser beam towards a plasma generation region; or
   a fuel target steering control signal indicative of a second electronic instruction to steer the fuel target towards the plasma generation region; and
the method further comprises:
   steering, by a laser steering actuator of a laser steering system, the laser beam towards the plasma generation region based on the laser steering control signal; or
   steering, by a fuel target steering actuator of a fuel target steering system, the fuel target towards the plasma generation region based on the fuel target steering control signal.

The breadth and scope of the present disclosure should not be limited by any of the above-described example aspects or embodiments, but should be defined only in accordance with the following claims and their equivalents.

1. A radiation source, comprising:
a first optical sensing device configured to generate, at a first rate, first sensing data indicative of a first overlap between a fuel target and a laser beam;
a second optical sensing device configured to generate, at a second rate, second sensing data indicative of a second overlap between the fuel target and the laser beam; and
a controller configured to:
receive the first sensing data and the second sensing data;
generate fuel target data based on the first sensing data and the second sensing data; and
generate, at a third rate and based on the fuel target data, a steering control signal configured to steer the laser beam or the fuel target.

2. The radiation source of claim 1, wherein:
the first optical sensing device comprises a photoreceiver;
the second optical sensing device comprises an imaging device;
the second rate is different from the first rate; and
the third rate is about equal to the first rate.

3. The radiation source of claim 1, wherein:
the first optical sensing device comprises a first droplet formation camera;
the second optical sensing device comprises a second droplet formation camera configured to be synchronized to the first droplet formation camera;
the second rate is about equal to the first rate; and
the third rate is about equal to the first rate.

4. The radiation source of claim 3, further comprising a dual droplet formation camera system comprising:
the first droplet formation camera, wherein the first sensing data is indicative of the first overlap between the fuel target and the laser beam obtained from a first angle at about a time that the laser beam is generated;
the second droplet formation camera, wherein the second sensing data is indicative of the second overlap between the fuel target and the laser beam obtained from a second angle at about the time that the laser beam is generated;
a first illumination device configured to illuminate the fuel target from a first illumination angle at about the time that the laser beam is generated; and
a second illumination device configured to illuminate the fuel target from a second illumination angle different from the first illumination angle at about the time that the laser beam is generated.

5. The radiation source of claim 4, wherein the laser beam comprises a pre-pulse laser beam.

6. The radiation source of claim 1, wherein the fuel target data comprises laser-to-droplet data.

7. The radiation source of claim 1, wherein the controller is further configured to:
generate stereoscopic sensing data based on the first sensing data and the second sensing data; and
generate the fuel target data based on the stereoscopic sensing data.

8. The radiation source of claim 1, wherein the controller is further configured to:
generate first estimated fuel target data;
generate a comparison of the fuel target data and the first estimated fuel target data;
generate fuel target estimation error data based on the comparison; and
generate second estimated fuel target data based on the fuel target data, the first estimated fuel target data, and the fuel target estimation error data.

9. The radiation source of claim 8, wherein:
the steering control signal is a first steering control signal; and
the controller is further configured to:
generate, at a first time, the first steering control signal based on the fuel target data; and
generate, at a second time different from the first time, a second steering control signal based on the second estimated fuel target data.

10. The radiation source of claim 8, wherein:
the comparison is a first comparison;
the fuel target estimation error data is first fuel target estimation error data;
the controller is further configured to:
generate a second comparison of the fuel target data and the second estimated fuel target data; and
generate second fuel target estimation error data based on the second comparison; and
the second fuel target estimation error data indicates an absence of an error between the fuel target data and the second estimated fuel target data.

11. The radiation source of claim 1, further comprising:
a laser steering system, wherein:
the steering control signal comprises a laser steering control signal indicative of an electronic instruction to steer the laser beam towards a plasma generation region; and
the controller is further configured to transmit the laser steering control signal to the laser steering system.

12. The radiation source of claim 11, wherein the laser steering system comprises a laser steering actuator configured to:
receive the laser steering control signal; and
steer the laser beam towards the plasma generation region based on the laser steering control signal.

13. The radiation source of claim 1, further comprising:
a fuel target steering system, wherein:
the steering control signal comprises a fuel target steering control signal indicative of an electronic instruction to steer the fuel target towards a plasma generation region; and
the controller is configured to transmit the fuel target steering control signal to the fuel target steering system.

14. The radiation source of claim 13, wherein the fuel target steering system comprises a fuel target steering actuator configured to:
receive the fuel target steering control signal; and
steer the fuel target towards the plasma generation region based on the fuel target steering control signal.

15. The radiation source of claim 1, wherein:
the steering control signal comprises:
a laser steering control signal indicative of a first electronic instruction to steer the laser beam; and
a fuel target steering control signal indicative of a second electronic instruction to steer the fuel target;
the controller is further configured to:
transmit the laser steering control signal to a laser steering system; and
transmit the fuel target steering control signal to a fuel target steering system.

16. An apparatus, comprising:
a controller configured to:
receive first sensing data captured at a first rate and indicative of a first overlap between a fuel target and a laser beam;
receive second sensing data captured at a second rate and indicative of a second overlap between the fuel target and the laser beam;
generate fuel target data based on the first sensing data and the second sensing data;
generate estimated fuel target data;
generate a comparison of the fuel target data and the estimated fuel target data;
generate fuel target estimation error data based on the comparison;
generate modified estimated fuel target data based on the fuel target data, the estimated fuel target data, and the fuel target estimation error data; and
generate, at a third rate and based on the modified estimated target data, a steering control signal configured to steer the laser beam or the fuel target.

17. The apparatus of claim 16, wherein:
the controller is further configured to:
receive the first sensing data from a first optical sensing device comprising a photoreceiver; and
receive the second sensing data from a second optical sensing device comprising an imaging device;
the second rate is different from the first rate; and
the third rate is about equal to the first rate.

18. The apparatus of claim 16, wherein:
the controller is further configured to:
receive the first sensing data from a first optical sensing device comprising a first droplet formation camera; and
receive the second sensing data from a second optical sensing device comprising a second droplet formation camera configured to be synchronized to the first droplet formation camera;
the second rate is about equal to the first rate; and
the third rate is about equal to the first rate.

19. A method comprising:
generating, by a first optical sensing device, first sensing data indicative of a first overlap between a fuel target and a laser beam;
generating, by a second optical sensing device, second sensing data indicative of a second overlap between the fuel target and the laser beam;
generating, by a controller, fuel target data based on the first sensing data and the second sensing data;
generating, by the controller, first estimated fuel target data;
generating, by the controller, a comparison of the fuel target data and the first estimated fuel target data;
generating, by the controller, fuel target estimation error data based on the comparison;
generating, by the controller, second estimated fuel target data based on the fuel target data, the first estimated fuel target data, and the fuel target estimation error data; and
generating, by the controller and based on the second estimated target data, a steering control signal configured to steer the laser beam or the fuel target.

20. The method of claim 19, wherein:
the steering control signal comprises:
a laser steering control signal indicative of a first electronic instruction to steer the laser beam towards a plasma generation region; or
a fuel target steering control signal indicative of a second electronic instruction to steer the fuel target towards the plasma generation region; and
the method further comprises:
steering, by a laser steering actuator of a laser steering system, the laser beam towards the plasma generation region based on the laser steering control signal; or
steering, by a fuel target steering actuator of a fuel target steering system, the fuel target towards the plasma generation region based on the fuel target steering control signal.
